(19) United States
(12) Patent Application Publication
(10) Pub. No.: US 2025/0312835 A1
(43) Pub. Date: Oct. 9, 2025

(54) GRAPHENE-NICKEL COMPOSITE WIRES

(71) Applicants: Wonjune Choi, Phoenix, AZ (US); Wonmo Kang, Scottsdale, AZ (US)

(72) Inventors: Wonjune Choi, Phoenix, AZ (US); Wonmo Kang, Scottsdale, AZ (US)

(21) Appl. No.: 19/171,029

(22) Filed: Apr. 4, 2025

Related U.S. Application Data
(60) Provisional application No. 63/575,256, filed on Apr. 5, 2024.

(51) Int. Cl. B21C 37/04; C22C 19/03; C22F 1/10; C23C 16/02; C23C 16/26

(52) U.S. Cl. CPC B21C 37/042; C22C 19/03; C22F 1/10; C23C 16/0227; C23C 16/26

(57) ABSTRACT

Disclosed herein are composite wire materials with advantageous composition and structure that can provide improved mechanical properties. An example composite wire material includes a core wire including nickel (Ni), and a graphene-based layer on a surface of the core wire. Also disclosed are methods of making the composite wire material.

### CROSS-REFERENCE TO RELATED APPLICATIONS

This application claims priority to U.S. Provisional Patent Application No. 63/575,256 filed on Apr. 5, 2024, which is incorporated fully herein by reference.

### STATEMENT OF GOVERNMENT INTEREST

This invention was made with government support under grant N00014-21-1-2396 awarded by the Office of Naval Research. The government has certain rights in the invention.

### INTRODUCTION

Small carbon materials, such as graphene, offer useful mechanical strength. Micro/nano carbon materials are often dispersed into a metal matrix to form bulk composites with mechanical enhancement. Despite technical progress, such composites can intrinsically suffer from a trade-off condition between strength and ductility.

### SUMMARY

In one aspect, disclosed are composite wire materials comprising a core wire comprising nickel (Ni); and a layer on a circumferential surface of the core wire, the layer comprising graphene.

In another aspect, disclosed are methods of making a composite wire material, the method comprising annealing a core wire comprising nickel (Ni) at a temperature of about 800° C. to about 1000° C. under flowing mixed gaseous conditions comprising argon (Ar) and hydrogen (H₂); and coating graphene on a circumferential surface of the core wire to generate a layer comprising the graphene.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A: Optical images of (a) 25_Ni_As-received, (b) 25_ANi_800, and (c) 25_ACGN_800 wires (see Table 2 for the naming convention). Scanning Electron Microscopy (SEM) images of (d) 100_ANi_1000 and (e) 100_ACGN_1000 wires. The arrows in (d) indicate the grain boundary of the annealed Ni wire. The arrows in (e) show the wrinkled graphene due to the thermal mismatch between graphene and Ni.

FIG. 1B: Raman spectra of (top) 25_ACGN_800 and (bottom) 25_ACGN_1000 from multiple positions on each wire.

FIG. 1C: A transmission electron microscopy (TEM) image of 100_ACGN_1000 including (from bottom to top) a Ni wire, graphene layers, and amorphous carbon.

FIG. 2A: Representative stress-strain curve of Ni wires (As-received, ANi, and ACGN) with 100 μm diameter. All stress-strain curves are in FIG. 12A-FIG. 12E.

FIG. 2B: Representative stress-strain curve of Ni wires (As-received, ANi, and ACGN) with 25 μm diameter. All stress-strain curves are in FIG. 13A-FIG. 13E.

FIG. 2C: Representative stress-strain curve of Ni wires (As-received, ANi, and ACGN) with 12.5 μm diameter. All stress-strain curves are in FIG. 14A-FIG. 14E.

FIG. 3A: Summary of yield strength of as-received, annealed, and graphene-coated Ni wires with different diameter from the stress-strain curves in FIG. 2A-2C.

FIG. 3B: Summary of ultimate tensile strength (σᵤ) of as-received, annealed, and graphene-coated Ni wires with different diameter from the stress-strain curves in FIG. 2A-2C.

FIG. 3C: Summary of failure strain (ε_{f}) of as-received, annealed, and graphene-coated Ni wires with different diameter from the stress-strain curves in FIG. 2A-2C.

FIG. 4A: SEM images of 25 μm-diameter wires including (left) 25_Ni_As-received, (middle) 25_ANi_1000, and (right) 25_ACGN_1000.

FIG. 4B: SEM images of 25 μm-diameter wires including (left) 12.5_Ni_As-received, (right).

FIG. 4C: SEM images of (left) 12.5_ANi_1000 and (right) 12.5_ACGN_1000. Slip bands were pointed by blue arrows. The delaminated graphene was pointed by white arrows, and wrinkled graphene was indicated by yellow arrows.

FIG. 5: Summary of normalized engineering failure strain (ε) and normalized engineering ultimate tensile strength (σ) for carbon-enhanced metal matrix composites. Black for homogeneous dispersion, green for laminated structure, orange for aligned structure, and blue for continuous 3D-network. Solid, open, and half-filled markers are for Al, Cu, and Ni matrix, respectively. Red stars within the yellow area for ACGN.

FIG. 6: ACGN wires with relatively larger (left) and smaller (right) diameters (D_{w}) with respect to average grain size (d) in Ni. mGr indicates multilayer graphene including N_{mGr} layers.

FIG. 7: Bar charts to estimate the strengthening from the graphene-nickel interplay (Δσ_{GN}). From Eq. 2, L=σ_{ACGN}−Δσ_{CTE} and R=σₘ+Δσ_{LS}+Δσₛₛ+Δσ_{GN} are directly compared for different wire diameters (D_{w}=100, 25, and 12.5 μm from left to right blue boxes, respectively) and chemical vapor deposition (CVD) temperatures (as indicated in each box, the left L-R pair for 800° C. and the right L-R pair for 1000° C., respectively).

FIG. 8: The number of grains (N_{d}) per unit length (L) for as-received and annealed Ni wires with different wire diameters (D_{w}). The inset is the zoom-in view of the area highlighted by a dotted line.

FIG. 9: (a) A schematic diagram of a tensile test system for mechanical characterization of micro-scale wires. (b) An image of the experimental setup. (c) A 3D-printed sample holder with a 25-μm-diameter Ni wire. (d) A magnified optical image of the Ni wire decorated with microbeads for image tracking using digital image correlation.

FIG. 10: The images of Ni wire after (a) annealing or (b) CVD process. Wires were wrapped around a Ni sample frame. (c) The schematic diagram of annealing or CVD process for Ni and Cu wire. The flow of benzene, heat treatment time and temperature for CVD is changed depending on the graphene growth conditions.

FIG. 11: (a) TEM analysis of 100_ACGN_1000 wire and (b) magnified image of the graphene layer. (c) Intensity profile following the scanning direction. The number of graphene layers was measured by counting the number of peaks.

FIG. 12A: Stress-strain curve of Ni wire with 100 μm diameter, 100_As-received.

FIG. 12B: Stress-strain curve of Ni wire with 100 μm diameter, 100_ANi_800.

FIG. 12C: Stress-strain curve of Ni wire with 100 μm diameter, 100_ACGN_800.

FIG. 12D: Stress-strain curve of Ni wire with 100 μm diameter, 100_ANi_1000.

FIG. 12E: Stress-strain curve of Ni wire with 100 μm diameter, 100_ACGN_1000.

FIG. 13A: Stress-strain curve of Ni wire with 25 μm diameter, 25_As-received.

FIG. 13B: Stress-strain curve of Ni wire with 25 μm diameter, 25_ANi_800.

FIG. 13C: Stress-strain curve of Ni wire with 25 μm diameter, 25_ACGN_800.

FIG. 13D: Stress-strain curve of Ni wire with 25 μm diameter, 25_ANi_1000.

FIG. 13E: Stress-strain curve of Ni wire with 25 μm diameter, 25_ACGN_1000.

FIG. 14A: Stress-strain curve of Ni wire with 100 μm diameter, 12.5_As-received.

FIG. 14B: Stress-strain curve of Ni wire with 100 μm diameter, 12.5_ANi_800.

FIG. 14C: Stress-strain curve of Ni wire with 100 μm diameter, 12.5_ACGN_800.

FIG. 14D: Stress-strain curve of Ni wire with 100 μm diameter, 12.5_ANi_1000.

FIG. 14E: Stress-strain curve of Ni wire with 100 μm diameter, 12.5_ACGN_1000.

FIG. 15: Electron backscatter diffraction (EBSD) analysis of Ni wires: (a) 100_Ni_As-received wire, (b) 100_ANi_800 wire, (c) 100_ANi_1000 wire, and (d) 100_ACGN_1000 wire. The grain size of 100_Ni_As-received, 100_ANi_800, _1000, and 1000_ACGN_1000 is 6.30, 10.11, and 21.69, 22.14 μm, respectively. The variations in color show grain boundaries and grain orientations.

FIG. 16: EBSD analysis of Ni wires: (a) 25_Ni_As-received wire, (b) 25_ANi_800 wire, and (c) 25_Ani_1000 wire. The grain size of 25_Ni_As-received, 25_ANi_800, and _1000 is 2.99, 6.66, and 9.80 μm, respectively. The variations in color show grain boundaries and grain orientations.

FIG. 17: EBSD analysis of Ni wires: (a) 12.5_Ni_As-received wire, (b) 12.5_ANi_800 wire, and (c) 12.5_Ani_1000 wire. The grain size of 12.5_Ni_As-received, 12.5_ANi_800, and _1000 is 2.94, 8.42, and 9.12 μm, respectively. The variations in color show grain boundaries and grain orientations.

FIG. 18: Schematic diagram of the load sharing mechanism under tensile stress on graphene-coated metal wire.

FIG. 19A: Diffusion profile of carbon after furnace cooling in 100 μm diameter Ni and at 800° C.

FIG. 19B: Diffusion profile of carbon after furnace cooling in 25 μm diameter Ni and at 800° C.

FIG. 19C: Diffusion profile of carbon after furnace cooling in 12.5 μm diameter Ni and at 800° C.

FIG. 19D: Diffusion profile of carbon after furnace cooling in 100 μm diameter Ni and at 1000° C.

FIG. 19E: Diffusion profile of carbon after furnace cooling in 25 μm diameter Ni and at 1000° C.

FIG. 19F: Diffusion profile of carbon after furnace cooling in 12.5 μm diameter Ni and at 1000° C.

FIG. 20: Schematic diagram of the thermal mismatch due to the discrepancy of coefficient of thermal expansion between graphene and metal matrix.

FIG. 21: Strain hardening exponent with respect to the wire's type (as-received, ANi, and ACGN).

FIG. 22: Specific values of yield strengths and strengthening effects for GNi wires which were used in FIG. 6.

### DETAILED DESCRIPTION

Graphene has received much attention due to its outstanding electrical/mechanical/thermal properties, two dimensional (2D) characteristics, and excellent chemical stability. With these superior material properties combined with the 2D nature, graphene has found a basis in many emerging technology innovations and advances including sensors, electronics, energy applications, and biomedical materials. In addition, graphene has been integrated with conventional bulk-scale materials, e.g., carbon-enhanced polymer matrix composites (CPMCs), ceramic matrix composites (CCMCs), and metal matrix composites (CMMCs), to achieve graphene-enhanced material properties of various composites.

For CMMC, the choice of a metal matrix typically depends on their applications, e.g., aluminum (Al) and titanium (Ti) for light-weight composites, copper (Cu) for high-performance conductors, and nickel (Ni) for structural applications. In these studies, small scale carbon materials, such as carbon nanotube and graphene flakes, are often dispersed in a much larger metal matrix. Owing to the popularity of this approach, many studies have focused on innovative techniques to disperse small carbon materials in the metal matrix including homogeneously dispersed, laminated, and aligned carbon materials in CMMCs. For example, molecular level mixing to form carbon/metal powders has been conducted for uniform dispersion of carbon materials in a matrix, and bio-mimicked brick-and-mortar structure has been adopted to make a highly aligned graphene structure. One common goal of these composites is integration of attractive advantages of both metal and carbon materials without compromising (or even with improving) the overall material performances of CMMCs.

As an example, ideal CMMCs for structural applications should offer both graphene-enhanced mechanical strength for structural robustness as well as ductility of the composites for sufficient manufacturability and prevention of catastrophic brittle failure. However, conventional CMMCs exhibit a strong trade-off condition between strength and ductility. The foremost reason is that the load transfer path between strong carbon materials is through the limited interfacial strength between the nano/microscale individual constituents and/or between the constituents and composite matrix. As a result, the intrinsically weak interfaces due to the short length and chemical inertness of carbon materials dominate mechanical failure of conventional CMMCs. In other words, CMMC becomes stronger with increasing carbon contents, but the weak interfaces also become abundant, which leads to premature failure within limited mechanical deformation.

To address this intrinsic challenge, recent research efforts have increasingly focused on integrating a continuous network of carbon materials with metal matrices through both experimental studies and molecular dynamic simulations. These emerging approaches have shown promising results toward breaking the strength-ductility trade-off condition in CMMCs. Despite the technical progress, the exact mechanism(s) of how continuous graphene interact with metal matrices during material deformation have not been fully understood due to the complex interplay between graphene and a metal matrix at different length scale, e.g., dislocations, grain boundaries, and dimensions of metal. As a result, there is still a gap between experimentally measured mechanical properties and theoretical predictions, which suggests potential to further enhance mechanical properties of CMMCs beyond what has been experimentally demonstrated.

In light of the current challenges in CMMCs, this disclosure presents advances utilizing, e.g., fine nickel (Ni) wires coated by continuous graphene structures, which are referred to as axially bi-continuous graphene-nickel (ACGN) composite wires. First, ACGN demonstrates that the intrinsic strength-ductility trade-off condition in CMMC can be broken by tailoring microstructures of both the metal matrix and graphene constituents. Second, the normalized improvement of combined strength and ductility achieved by ACGN in the present disclosure is the highest among Ni, Al, and Cu-based CMMCs reported.

The effect of continuous graphene on mechanical properties of ACGN wires was quantified, including yield stress, ultimate strength, and failure strain. Microscale nickel (Ni) wires coated by either mono/double-layers or multilayers (Gr or mGr) were used, respectively, as a model composite because of a wide use of Ni in structural CMMCs and ease of Gr- or mGr-Ni integration via chemical vapor deposition (CVD). Stress-strain responses of ACGN wires with different diameters, from 12.5 to 100 μm, were obtained by using a custom-built tensile tester designed for microwires. The experimental results indicate that the mechanical properties of ACGN wires can depend on three parameters, namely, the number of graphene layers, diameter of each Ni wire (D_w), and Ni grain size (d). More importantly, the ACGN wires exhibit considerably improved mechanical properties, in both ultimate strength and failure strain, compared to their pure Ni counterparts. For example, ultimate strength and failure strain of 25-μm-diameter ACGN wires were 71.76% and 58.30% higher compared to the same diameter pure Ni wires, respectively, with similar microstructures within Ni. Owing to the simpler structures of ACGN, compared to other CMMCs, contributions of different strengthening mechanisms, such as load sharing, residual stress due to thermal mismatch between metal and graphene, and solid solution strengthening, in ACGN are theoretically considered.

### 1. DEFINITIONS

Unless otherwise defined, all technical and scientific terms used herein have the same meaning as commonly understood by one of ordinary skill in the art. In case of conflict, the present document, including definitions, will control. The materials, methods, and examples disclosed herein are illustrative only and not intended to be limiting. Methods and materials similar or equivalent to those described herein can be used in practice or testing of the disclosed technology. All publications, patent applications, patents and other references mentioned herein are incorporated by reference in their entirety.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The singular forms “a,” “and” and “the” include plural references unless the context clearly dictates otherwise. The present disclosure also contemplates other embodiments “comprising,” “consisting of” and “consisting essentially of,” the embodiments or elements presented herein, whether explicitly set forth or not.

The modifier “about” used in connection with a quantity is inclusive of the stated value and has the meaning dictated by the context (for example, it includes at least the degree of error associated with the measurement of the particular quantity). The modifier “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5 to 1.4.

For the recitation of numeric ranges herein, each intervening number there between with the same degree of precision is explicitly contemplated. For example, for the range of 6-9, the numbers 7 and 8 are contemplated in addition to 6 and 9, and for the range 6.0-7.0, the numbers 6.0, 6.1, 6.2, 6.3, 6.4, 6.5, 6.6, 6.7, 6.8, 6.9, and 7.0 are contemplated, and for the range 1.5-2, the numbers 1.5, 1.6, 1.7, 1.8, 1.9, and 2 are contemplated.

Definitions of specific functional groups and chemical terms are described in more detail below. For purposes of this disclosure, the chemical elements are identified in accordance with the Periodic Table of the Elements, CAS version, Handbook of Chemistry and Physics, 75th Ed., inside cover, and specific functional groups are generally defined as described therein.

The disclosed technology has multiple aspects, illustrated by the following non-limiting examples.

### 2. COMPOSITE WIRE MATERIALS

Disclosed herein are composite wire materials with improved mechanical properties. The composite wire material includes a core wire and a layer on a surface of the core wire. The core wire can include nickel (Ni), and the layer can be a graphene-based layer on a circumferential surface of the core wire.

The composite wire material can include varying amounts of graphene relative to nickel (Ni). For example, the composite wire material can have a graphene-to-nickel (Ni) volume fraction of about 0.001 vol. % to about 0.5 vol. %, such as about 0.005 vol. % to about 0.5 vol. %, about 0.005 vol. % to about 0.4 vol. %, about 0.01 vol. % to about 0.5 vol. %, about 0.05 vol. % to about 0.5 vol. %, about 0.001 vol. % to about 0.1 vol. %, about 0.001 vol. % to about 0.01 vol. %, or about 0.1 vol. % to about 0.5 vol. %. In some embodiments, the composite wire material has a graphene-to-nickel (Ni) volume fraction of greater than or equal to 0.001 vol. %, greater than or equal to 0.002 vol. %, greater than or equal to 0.003 vol. %, greater than or equal to 0.004 vol. %, greater than or equal to 0.005 vol. %, greater than or equal to 0.007 vol. %, greater than or equal to 0.009 vol. %, greater than or equal to 0.01 vol. %, greater than or equal to 0.015 vol. %, greater than or equal to 0.02 vol. %, greater than or equal to 0.05 vol. %, greater than or equal to 0.1 vol. %, or greater than or equal to 0.2 vol. %. In some embodiments, the composite wire material has a graphene-to-nickel (Ni) volume fraction of less than or equal to 0.5 vol. %, less than or equal to 0.4 vol. %, less than or equal to 0.3 vol. %, less than or equal to 0.2 vol. %, less than or equal to 0.1 vol. %, less than or equal to 0.09 vol. %, less than or equal to 0.05 vol. %, less than or equal to 0.01 vol. %, or less than or equal to 0.009 vol. %.

The composite wire material can have advantageous mechanical properties based on its composition and structure. In particular, the interface between the core wire and the graphene layer can provide beneficial interactions that can enhance mechanical properties of the composite wire material. For example, the core wire and the layer can include a matched lattice system between the nickel (Ni) and graphene. This can be described as the interface being bonded by the electrons of the nickel (Ni) and the TT-orbitals of graphene. These advantageous interfacial interactions can in turn instill improved mechanical properties to the composite wire material such as, but not limited to, ultimate strength, yield strength, and failure strain.

The composite wire material can have an ultimate strength of greater than or equal to 200 MPa, greater than or equal to 225 MPa, greater than or equal to 250 MPa, greater than or equal to 275 MPa, greater than or equal to 300 MPa, greater than or equal to 350 MPa, greater than or equal to 400 MPa, greater than or equal to 450 MPa, or greater than or equal to 500 MPa. In some embodiments, the composite wire material has an ultimate strength of at least 1.1× greater than a control wire material (e.g., a core wire comprising nickel (Ni) but without a graphene layer and that has the same thermal history), such as at least 1.2× greater than a control wire material, at least 1.3× greater than a control wire material, at least 1.4× greater than a control wire material, at least 1.5× greater than a control wire material, or at least 2× greater than a control wire material.

The composite wire material can have a yield strength of greater than or equal to 95 MPa, greater than or equal to 100 MPa, greater than or equal to 125 MPa, greater than or equal to 150 MPa, greater than or equal to 175 MPa, or greater than or equal to 200 MPa. In some embodiments, the composite wire material has a yield strength of at least 1.1× greater than a control wire material (e.g., a core wire comprising nickel (Ni) but without a graphene layer and that has the same thermal history), such as at least 1.2× greater than a control wire material, at least 1.3× greater than a control wire material, at least 1.4× greater than a control wire material, at least 1.5× greater than a control wire material, or at least 2× greater than a control wire material.

The composite wire material can also have a failure strain of greater than or equal to 6%, 7%, 8%, 9%, 10%, 11%, 12%, 13%, 14%, 15%, 16%, 17%, 18%, 19%, or 20%. In some embodiments, the composite wire material has a failure strain of at least 1.1× greater than a control wire material (e.g., a core wire comprising nickel (Ni) but without a graphene layer and that has the same thermal history), such as at least 1.2× greater than a control wire material, at least 1.3× greater than a control wire material, at least 1.4× greater than a control wire material, at least 1.5× greater than a control wire material, or at least 2× greater than a control wire material.

### A. Core Wires

The core wire can include nickel (Ni) in varying amounts. For example, the core wire can include about 90% to about 100% pure nickel (Ni), such as about 91% to about 99.99% pure nickel (Ni), about 92% to about 99.99% pure nickel (Ni), about 93% to about 99.99% pure nickel (Ni), about 94% to about 99.99% pure nickel (Ni), about 95% to about 99.99% pure nickel (Ni), about 96% to about 99.99% pure nickel (Ni), about 97% to about 99.99% pure nickel (Ni), about 98% to about 99.99% pure nickel (Ni), or about 99% to 99.99% pure nickel (Ni). In some embodiments, the core wire includes pure nickel (Ni) at greater than or equal to 90%, greater than or equal to 91%, greater than or equal to 92%, greater than or equal to 93%, greater than or equal to 94%, greater than or equal to 95%, greater than or equal to 96%, greater than or equal to 97%, greater than or equal to 98%, or greater than or equal to 99%. In some embodiments, the core wire includes pure nickel (Ni) at less than or equal to 99.99%, less than or equal to 99%, less than or equal to 98%, or less than or equal to 97%. In some embodiments, the core wire includes about 99.0% pure nickel (Ni).

The core wire can have a varying diameter. For example, the core wire can have a diameter of about 10 μm to about 150 μm, such as about 10 μm to about 125 μm, about 10 μm to about 100 μm, about 11 μm to about 120 μm, about 12 μm to about 115 μm, about 12 μm to about 100 μm, about 10 μm to about 50 μm, or about 50 μm to about 150 μm. In some embodiments, the core wire has a diameter of greater than or equal to 10 μm, greater than or equal to 11 μm, greater than or equal to 12 μm, greater than or equal to 15 μm, greater than or equal to 20 μm, greater than or equal to 30 μm, greater than or equal to 40 μm, greater than or equal to 50, greater than or equal to 60 μm, greater than or equal to 70 μm, or greater than or equal to 80 μm. In some embodiments, the core wire has a diameter of less than or equal to 150 μm, less than or equal to 140 μm, less than or equal to 130 μm, less than or equal to 120 μm, less than or equal to 110 μm, less than or equal to 100 μm, less than or equal to 90 μm, less than or equal to 80, less than or equal to 70 μm, less than or equal to 60 μm, or less than or equal to 50 μm. Diameter of the core wire can be measured by techniques known within the art such as, but not limited to, electron microscopy (e.g., SEM, TEM, etc.).

The core wire can have a varying nickel (Ni) grain size. For example, the nickel (Ni) can have a grain size of about 5 μm to about 25 μm, such as about 5 μm to about 24 μm, about 5.5 μm to about 23 μm, about 6 μm to about 23 μm, about 6 μm to about 22.5 μm, about 5 μm to about 15 μm, or about 15 μm to about 25 μm. In some embodiments, the nickel (Ni) has a grain size of greater than or equal to 5 μm, greater than or equal to 5.5 μm, greater than or equal to 6 μm, greater than or equal to 6.5 μm, greater than or equal to 7 μm, greater than or equal to 8 μm, greater than or equal to 9 μm, or greater than or equal to 10 μm. In some embodiments, the nickel (Ni) has a grain size of less than or equal to 25 μm, less than or equal to 24 μm, less than or equal to 23.5 μm, less than or equal to 23 μm, less than or equal to 22.5 μm, less than or equal to 22 μm, less than or equal to 21 μm, or less than or equal to 20 μm. Grain size can be measured by techniques known within the art such as, but not limited to, EBSD.

### B. Layers

The layer can include graphene. In some embodiments, the layer includes graphene, benzene, amorphous carbon, or a combination thereof. In some embodiments, the layer consists essentially of graphene, a combination of graphene and benzene, a combination of graphene and amorphous carbon, or a combination of graphene, benzene, and amorphous carbon. In some embodiments, the layer consists of graphene, a combination of graphene and benzene, a combination of graphene and amorphous carbon, or a combination of graphene, benzene, and amorphous carbon. The layer may include an intensity ratio of graphene of 2D and G bands (I₂D/I_{G} ratio) of about 0.7 to about 1.5, such as about 0.74 to about 1.4, about 0.7 to about 1, or about 0.75 to about 1.5. In some embodiments, the layer includes an intensity ratio of graphene of 2D and G bands (I₂D/I_{G} ratio) of greater than or equal to 0.7, greater than or equal to 0.74, greater than or equal to 0.75, greater than or equal to 0.9, or greater than or equal to 1. In some embodiments, the layer includes an intensity ratio of graphene of 2D and G bands (I₂D/I_{G} ratio) of less than or equal to 1.5, less than or equal to 1.4, less than or equal to 1.3, less than or equal to 1.2, less than or equal to 1.1, or less than or equal to 1.

The layer can include one or more layers of graphene. In other words, the layer can include a plurality of graphene layers. For example, the layer can include about 1 to about 50 graphene layers, such as about 1 to about 45 graphene layers, about 1 to about 40 graphene layers, about 1 to about 30 graphene layers, about 1 to about 20 graphene layers, about 1 to about 10 graphene layers, about 1 to about 9 graphene layers, about 1 to about 8 graphene layers, about 1 to about 7 graphene layers, about 1 to about 6 graphene layers, about 1 to about 5 graphene layers, about 1 to about 4 graphene layers, about 1 to about 3 graphene layers, or about 1 to about 2 graphene layers. In some embodiments, the layer includes greater than or equal to 1 graphene layer, greater than or equal to 2 graphene layers, greater than or equal to 3 graphene layers, greater than or equal to 4 graphene layers, greater than or equal to 5 graphene layers, greater than or equal to 10 graphene layers, greater than or equal to 15 graphene layers, or greater than or equal to 20 graphene layers. In some embodiments, the layer includes less than or equal to 50 graphene layers, less than or equal to 45 graphene layers, less than or equal to 40 graphene layers, less than or equal to 30 graphene layers, less than or equal to 20 graphene layers, less than or equal to 15 graphene layers, less than or equal to 10 graphene layers, less than or equal to 5 graphene layers, or less than or equal to 2 graphene layers. The number of graphene layers can be measured by techniques known within the art such as, but not limited to, electron microscopy (e.g., SEM, TEM, etc.).

The layer can have a varying thickness. For example, the layer can have a thickness of about 0.3 nm to about 20 nm, such as about 0.3 nm to about 18 nm, about 0.3 nm to about 14 nm, about 0.35 nm to about 14 nm, about 0.35 nm to about 13.7 nm, about 0.4 nm to about 13 nm, about 0.5 nm to about 12 nm, about 0.3 nm to about 10 nm, or about 7 nm to about 14 nm. In some embodiments, the layer has a thickness of greater than or equal to 0.3 nm, greater than or equal to 0.35 nm, greater than or equal to 0.5 nm, greater than or equal to 1 nm, greater than or equal to 2 nm, greater than or equal to 3 nm, greater than or equal to 4 nm, greater than or equal to 5 nm. In some embodiments, the layer has a thickness of less than or equal to 20 nm, less than or equal to 18 nm, less than or equal to 14 nm, less than or equal to 13.7 nm, less than or equal to 13 nm, less than or equal to 12 nm, less than or equal to 11 nm, less than or equal to 10 nm, less than or equal to 9 nm, less than or equal to 8 nm, less than or equal to 7 nm, less than or equal to 6 nm, or less than or equal to 5 nm.

### 3. METHODS OF MAKING COMPOSITE WIRE MATERIALS

Also disclosed herein are methods of making the composite wire materials. The method can include annealing a core wire, the core wire including nickel (Ni). Annealing the core wire can be done at about 800° C. to about 1000° C., such as about 825° C. to about 975° C., about 850° C. to about 950° C., about 875° C. to about 925° C., about 800° C. to about 900° C., or about 900° C. to about 1000° C. In some embodiments, the core wire is annealed at greater than or equal to 800° C., greater than or equal to 810° C., greater than or equal to 815° C., greater than or equal to 820° C., greater than or equal to 850° C., or greater than or equal to 900° C. In some embodiments, the core wire is annealed at less than or equal to 1000° C., less than or equal to 990° C., less than or equal to 980° C., less than or equal to 970° C., less than or equal to 950° C., or less than or equal to 900° C. In some embodiments, the core wire is annealed at about 800° C.

The core wire can be annealed under flowing mixed gaseous conditions. The flowing mixed gaseous conditions can include argon (Ar) and hydrogen (H₂). The flowing mixed gaseous conditions can include about 1400 standard cubic centimeters per minute (sccm) to about 1600 sccm argon (Ar), such as about 1425 sccm to about 1575 sccm argon (Ar), about 1450 sccm to about 1550 sccm argon (Ar), about 1475 sccm to about 1525 sccm argon (Ar), about 1400 sccm to about 1500 sccm argon (Ar), or about 1500 sccm to about 1600 sccm argon (Ar). In some embodiments, the flowing mixed gaseous conditions include greater than or equal to 1400 sccm argon (Ar), greater than or equal to 1410 sccm argon (Ar), greater than or equal to 1415 sccm argon (Ar), greater than or equal to 1420 sccm argon (Ar), greater than or equal to 1450 sccm argon (Ar), or greater than or equal to 1500 sccm argon (Ar). In some embodiments, the flowing mixed gaseous conditions include less than or equal to 1600 sccm argon (Ar), less than or equal to 1590 sccm argon (Ar), less than or equal to 1585 sccm argon (Ar), less than or equal to 1580 sccm argon (Ar), less than or equal to 1550 sccm argon (Ar), or less than or equal to 1500 sccm argon (Ar).

The flowing mixed gaseous conditions (for annealing) can include about 75 sccm to about 125 sccm hydrogen (H₂), such as about 80 sccm to about 120 sccm hydrogen (H₂), about 85 sccm to about 115 sccm hydrogen (H₂), about 90 sccm to about 110 sccm hydrogen (H₂), about 75 sccm to about 100 sccm hydrogen (H₂), or about 100 sccm to about 125 sccm hydrogen (H₂). In some embodiments, the flowing mixed gaseous conditions include greater than or equal to 75 sccm hydrogen (H₂), greater than or equal to 80 sccm hydrogen (H₂), greater than or equal to 85 sccm hydrogen (H₂), greater than or equal to 90 sccm hydrogen (H₂), greater than or equal to 95 sccm hydrogen (H₂), or greater than or equal to 100 sccm hydrogen (H₂). In some embodiments, the flowing mixed gaseous conditions include less than or equal to 125 sccm hydrogen (H₂), less than or equal to 120 sccm hydrogen (H₂), less than or equal to 115 sccm hydrogen (H₂), less than or equal to 110 sccm hydrogen (H₂), less than or equal to 105 sccm hydrogen (H₂), or less than or equal to 100 sccm hydrogen (H₂). The flowing mixed gaseous conditions described for annealing can also be applied to the coating step discussed below.

Annealing the core wire under flowing mixed gaseous conditions can be done for about 5 minutes to about 15 minutes, such as about 6 minutes to about 14 minutes, about 7 minutes to about 13 minutes, about 8 minutes to about 12 minutes, about 5 minutes to about 12 minutes, or about 9 minutes to about 15 minutes. In some embodiments, annealing the core wire under flowing mixed gaseous conditions is done for greater than or equal to 5 minutes, greater than or equal to 6 minutes, greater than or equal to 7 minutes, greater than or equal 8 minutes, or greater than or equal to 9 minutes. In some embodiments, annealing the core wire under flowing mixed gaseous conditions is done for less than or equal to 15 minutes, less than or equal to 14 minutes, less than or equal to 13 minutes, less than or equal 12 minutes, or less than or equal to 11 minutes.

The method can further include coating graphene on a circumferential surface of the core wire (e.g., annealed core wire) to generate a layer comprising the graphene. Coating graphene onto the core wire can include chemical vapor depositing (CVD) benzene onto the surface of the core wire. CVD of benzene can be done at a flow rate of about 5 sccm to about 25 sccm, such as about 6 sccm to about 24 sccm, about 7 sccm to about 23 sccm, about 8 sccm to about 22 sccm, about 9 sccm to about 21 sccm, or about 10 sccm to about 20 sccm. In some embodiments, CVD of benzene is done at greater than or equal to 5 sccm, greater than or equal to 6 sccm, greater than or equal to 7 sccm, greater than or equal to 8 sccm, greater than or equal to 9 sccm, or greater than or equal to 10 sccm. In some embodiments, CVD of benzene is done at less than or equal to 25 sccm, less than or equal to 24 sccm, less than or equal to 23 sccm, less than or equal to 22 sccm, less than or equal to 21 sccm, or less than or equal to 20 sccm.

CVD of benzene can be done at varying temperatures. For example, CVD of benzene can be done at about 800° C. to about 1000° C., such as about 825° C. to about 975° C., about 850° C. to about 950° C., about 875° C. to about 925° C., about 800° C. to about 900° C., or about 900° C. to about 1000° C. In some embodiments, CVD of benzene is done at greater than or equal to 800° C., greater than or equal to 810° C., greater than or equal to 815° C., greater than or equal to 820° C., greater than or equal to 850° C., or greater than or equal to 900° C. In some embodiments, CVD of benzene is done at less than or equal to 1000° C., less than or equal to 990° C., less than or equal to 980° C., less than or equal to 970° C., less than or equal to 950° C., or less than or equal to 900° C.

CVD of benzene can be done for about 5 minutes to about 15 minutes, such as about 6 minutes to about 14 minutes, about 7 minutes to about 13 minutes, about 8 minutes to about 12 minutes, about 5 minutes to about 12 minutes, or about 9 minutes to about 15 minutes. In some embodiments, CVD of benzene is done for greater than or equal to 5 minutes, greater than or equal to 6 minutes, greater than or equal to 7 minutes, greater than or equal 8 minutes, or greater than or equal to 9 minutes. In some embodiments, CVD of benzene is done for less than or equal to 15 minutes, less than or equal to 14 minutes, less than or equal to 13 minutes, less than or equal 12 minutes, or less than or equal to 11 minutes. The foregoing time ranges for the CVD of benzene can also be applied to the coating graphene step generally.

The coating of graphene can generate one or more layers on the circumferential surface of the core wire, each layer comprising graphene. In other words, the layer can include a plurality of graphene layers.

The method can also include a cleaning step prior to annealing. For example, the method can include the core wire being cleaned under flowing mixed gaseous conditions comprising argon (Ar) and hydrogen (H₂) for about 5 minutes to about 1 hour (e.g., 10 minutes to about 45 minutes, 15 minutes to about 35 minutes, or about 30 minutes) prior to annealing. The flowing mixed gaseous conditions during the cleaning can be about 650 sccm to about 850 sccm argon (Ar) (e.g., about 700 sccm to about 800 sccm or about 750 sccm) and about 20 sccm to about 40 sccm hydrogen (H₂) (e.g., about 25 to about 35 sccm or about 30 sccm).

The method and steps thereof can be done under vacuum. For example, the cleaning of the core wire, the annealing of the core wire, the coating of the core wire, or a combination thereof can be done under vacuum. In some embodiments, the method is done under vacuum.

The description above for the composite wire material, the core wire, and the layer can also be applied to the methods of making described herein.

### 4. EXAMPLES

### Example 1

### Materials & Methods

### Sample Preparation and Graphene Growth Via Chemical Vapor Deposition (CVD)

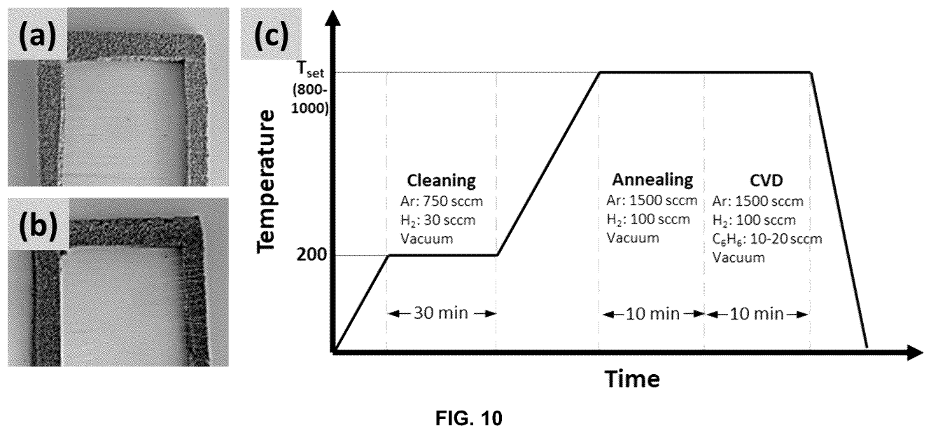

Ni wires with 100, 25, and 12.5-μm diameters and Cu wires with a 25-μm diameter were used from the California Fine Wire (California, USA) and Goodfellow (Pennsylvania, USA). The microscale wires were wrapped around a Ni metal frame with caution to avoid any unwanted damage or deformation of the wires (FIG. 10). The wires were put in the quartz tube of a thermal furnace, and chemical vapor deposition (CVD) process was performed for graphene growth under the following conditions. First, vacuum (<10-2 mbar) and purging (Ar gas) processes were repeated at least three times at 200° C. to eliminate contaminants. Then, temperature was increased to either 800° C. or 1000° C. for Ni wires and 1000° C. for Cu wires, respectively, to control the number of CVD-grown graphene layers. Note that considering the solubility of carbon into metal matrix based on the phase diagram (0.008 wt. % of carbon solubility into Cu at 1084.9° C. and 0.6 wt. % into Ni at 1326.5° C.), the solubility of Ni is higher and more sensitive to temperature compared to Cu and, therefore, Ni allows synthesis of a broader range of graphene structures from a few to tens of layers. While maintaining temperature, annealing was performed under Ar (1500 sccm) and H₂ (100 sccm) environment to remove a residual oxide layer on wire surfaces. For graphene growth, additional benzene flow (10-20 sccm) was introduced to the quartz tube. Benzene was decomposed to carbon atoms and then graphene layers were precipitated on the wire surface during the cooling. For clarification, 100, 25, and 12.5-μm-diameter Ni wires were processed together so that process-dependent sample-to-sample variation can be eliminated. All annealed wires were prepared by following the fabrication steps of their CVD-processed counterparts except using benzene. The annealing conditions are summarized in Table 1 and FIG. 10 at (c).

TABLE 1
Mechanical property and grain size of Ni wire. The nominal property from the material vendor
was indicated, and as-received, annealed (ANi), and graphene-coated (ACGN) Ni wires were
characterized by the tensile tester. The grain size was measured via the EBSD analysis.

| | | | Yield strength, | Ultimate | | |
|---|---|---|---|---|---|---|
| | Diameter | | σ_{y} | tensile | | Grain |
| | of wire | | (0.2% offset, | strength, σᵤ | Failure strain | size |
| Materials | (μm) | Sample name | MPa) | (MPa) | (%) | (μm) |
| Ni | 100 | Ref (from | 187.49 | 365.63 | 20.35 | — |
| | | vendor) | | | | |
| | | As-received | 205.18 | 352.59 | 20.08 | 6.30 |
| | | 100_ANi_800 | 103.10 | 307.19 | 19.84 | 10.11 |
| | | 100_ACGN_800 | 187.50 | 522.55 | 21.84 | |
| | | 100_ANi_1000 | 81.13 | 252.34 | 19.06 | 21.69 |
| | | 100_ACGN_{—} | 139.49 | 566.11 | 22.46 | 22.14* |
| | | 1000 | | | | |
| | 25 | Ref (from | 201.80 | 334.50 | 11.60 | — |
| | | vendor) | | | | |
| | | As-received | 211.08 | 326.55 | 13.73 | 2.99 |
| | | 25_ANi_800 | 153.35 | 251.46 | 7.65 | 6.66 |
| | | 25_ACGN_800 | 214.93 | 431.92 | 12.11 | |
| | | 25_ANi_1000 | 73.79 | 184.60 | 6.23 | 9.80 |
| | | 25_ACGN_{—} | 99.37 | 269.90 | 7.51 | |
| | | 1000 | | | | |
| | 12.5 | Ref (from | 247.82 | 299.52 | 2.46 | — |
| | | vendor) | | | | |
| | | As-received | 283.24 | 334.50 | 3.38 | 2.94 |
| | | 12.5_ANi_800 | 80.45 | 172.00 | 5.88 | 8.42** |
| | | 12.5_ACGN_{—} | 126.50 | 242.52 | 6.91 | |
| | | 800 | | | | |
| | | 12.5_ANi_1000 | 64.55 | 144.77 | 5.64 | 9.12** |
| | | 12.5_ACGN_{—} | 96.98 | 201.05 | 7.25 | |
| | | 1000 | | | | |

*Grain size of 100_ACGN_1000 wire was measured as a representation to compare the grain size of wires with/without carbon source at high-temperature.
**Due to the limited diameter of the wire the grain size may be measured smaller than the actual size.

### Tensile Test for Micro-Scale Wires

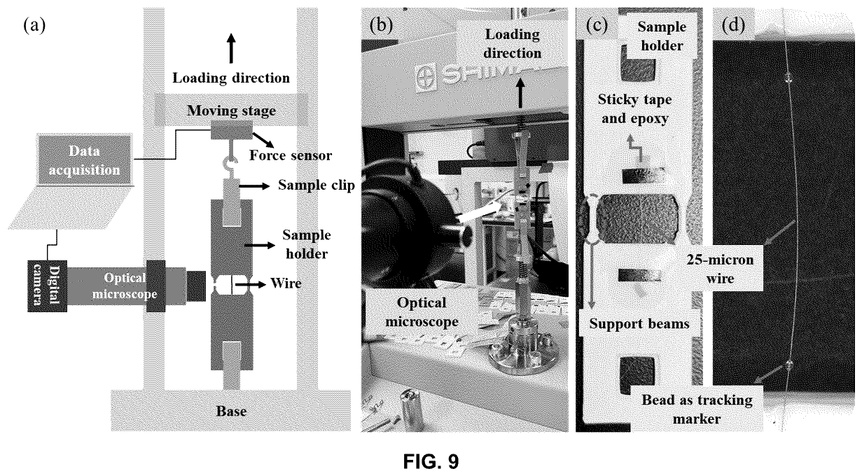

Characterization of mechanical properties is considerably challenging for small-scale wires. For example, such wires can be easily damaged or deformed by applying small force during sample handling and preparation due to their small cross section. In addition, high-resolution force and displacement sensors are required to accurately measure small applied force and the corresponding deformation. To address these challenges and test fine wire samples, a commercial tensile tester (AGS-10kNXD, Shimadzu), a custom-designed sample holder, the optical microscope and digital camera (H800-2713S-3MF, Amscope) were used to measure sample deformation, and a data acquisition system as shown in FIG. 9.

FIG. 9 at (a) and FIG. 9 at (b) show a schematic diagram of the tensile tester and an actual image of the experiment setup, respectively. Uniaxial tension acting on the wire was measured by the load cell of the commercial universal tester, while the deformation of the wire was monitored via a Matlab-based digital image correlation (DIC) method. Each wire was carefully placed and fixed onto a 3D printed sample holder by using adhesive tape and epoxy as shown FIG. 9 at (c). Then, the wire was decorated by two microbeads near the upper and lower ends of the wire (see FIG. 9 at (d)), and these beads were used as references for automated DIC analysis. Third, two rectangular holes near the top and bottom of the sample holder were aligned with the tensile tester and then fixed onto the sample clips. After the holder was fully engaged with the clips, two supportive beams, connecting upper and lower parts of the sample holder, were gently removed by using a soldering gun without applying any excessive force. It is worth noting that the two beams provide mechanical support during sample handling and preparation and allow gentle removal using their low melting temperature. These are important characterizations to prevent unwanted damage and deformation of wire samples. Finally, the distance between the separated sample holders was increased at 10-20 μm/min depending on wire's diameter. Note that more than one thousand images were captured during each test. The detailed experiment procedure is also described in Choi et al., Electro-thermo-mechanical characterization of microscale Ti-6Al-4V wires using an innovative experimental method, Materials Characterization, (2022) 111927, which is incorporated by reference herein in its entirety.

### Characterization

The quantitative and qualitative analyses of graphene were conducted via the Raman spectrometer (custom-built) using a green laser (532 nm wavelength). 6 mW of laser power was applied to at least five random points on the wire for ten seconds of accumulation time. The microstructure of the wires was investigated via the optical microscope (OM, VHX-7000, Keyence) and scanning electron microscope (SEM, Helios 5 UX, ThermoFisher Scientific). The grain size was analyzed using the SEM (Auriga, Zeiss) with electron backscatter diffraction (EBSD, Symmetry S2, Oxford instruments). A scanning transmission electron microscope (STEM, JEM-ARM200F, JEOL) was used for the qualitative/quantitative characterization of graphene.

### Load Transfer Mechanism

Assuming that the graphene-coated metal wire receives a force, Fₜₒₜₐₗ, it can be separated into F₁ and F₂, which are the applied force to metal core and graphene layer, respectively (Fₜₒₜₐₗ=Fₘ+F_{gra}). If the force is substituted to the stress term

$$( σ = \frac{F}{A} ,$$

where σ is a stress and A is a cross-sectional area), a equation can be obtained like right: σₜₒₜₐₗAₜₒₜₐₗ=σₘAₘ+σ_{gra}A_{gra}. As a result, total stress can be defined by the stresses and areas of metal and graphene, i.e.,

$${σ}_{total} = \frac{{σ}_{m} {A}_{m}}{{A}_{total}} + \frac{{σ}_{gra} {A}_{gra}}{{A}_{total}} .$$

In addition,

$$\frac{{A}_{m}}{{A}_{total}} and \frac{{A}_{gra}}{{A}_{total}}$$

are same with the volume fraction of metal and graphene (Vₘ and V_{gra}), respectively, because of the cylindrical shape of wire. Therefore, a final equation can be obtained for load-transfer mechanism on graphene-coated metal wire: σ_{LT}=σₘVₘ+σ_{gra}V_{gra}.

### Diffusion Profile

Assuming that the carbon atoms are solid solution at high temperature and will be diffused out from the metal matrix during the cooling to room temperature, the residual amount of solid solution carbon can be calculated by the concentration gradient, i.e., Fick's law. It is assumed that the initial concentration of carbon is dependent on the temperature, and concentration of carbon at surface is zero.

### Thermal Mismatch

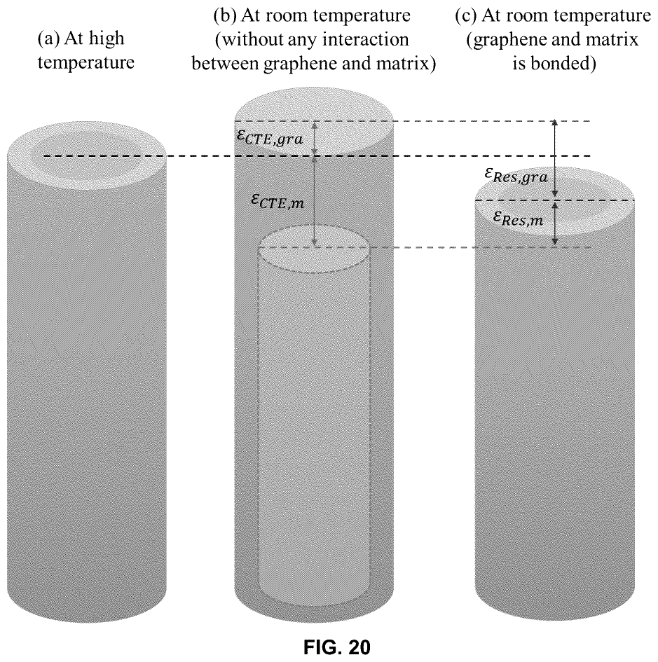

Graphene was synthesized at 800° C. or 1000° C. and went through the cooling process. At room temperature, the composite includes graphene and metal keeps its shape with little change of dimension (FIG. 20) if there is no fracture of materials or slip between graphene and metal during the cooling process. Due to the discrepancy of the coefficient of thermal expansion between graphene and metal, they are under the opposite direction of stress. For example, graphene is under compressive stress while metal is under tensile stress. This causes a residual stress within the composite wire. Assuming that the graphene and metal are strongly adhesive and have a similar strain history from elevated to room temperature, the strain equation can be described like the right-hand side: ε_{CTE,m}+ε_{Res,m}=ε_{CTE,gra}−ε_{Res,gra}, where ε_{CTE,m} and ε_{CTE,gra} are strains due to the thermal expansion or shrinkage by temperature change, ε_{Res,m} and ε_{Res,gra} are strains caused by the residual stress. Note that strain of graphene and metal caused by the residual stress has opposite direction. The above equation can be expressed with detail like the right-hand side:

$${α}_{m} ( {T}_{f} - {T}_{i} ) + \frac{F}{{E}_{m} {A}_{m}} = {α}_{gra} ( {T}_{f} - {T}_{i} ) - \frac{F}{{E}_{gra} {A}_{gra}} ,$$

where αₘ and α_{gra} are the coefficients of thermal expansion of metal and graphene, respectively, T_{f} and Tᵢ are a final and initial temperature, F is a internal force, Eₘ and E_{gra} are elastic modulus of metal and graphene, respectively, Aₘ and A_{gra} are cross-sectional area of metal and graphene, respectively. With an assumption that force is uniformly dispersed, not localized, the residual force can be defined like below:

$$F = \frac{( {T}_{f} - {T}_{i} ) ( {α}_{gra} - {α}_{m} )}{( \frac{1}{{E}_{m} {A}_{m}} + \frac{1}{{E}_{gra} {A}_{gra}} )}$$

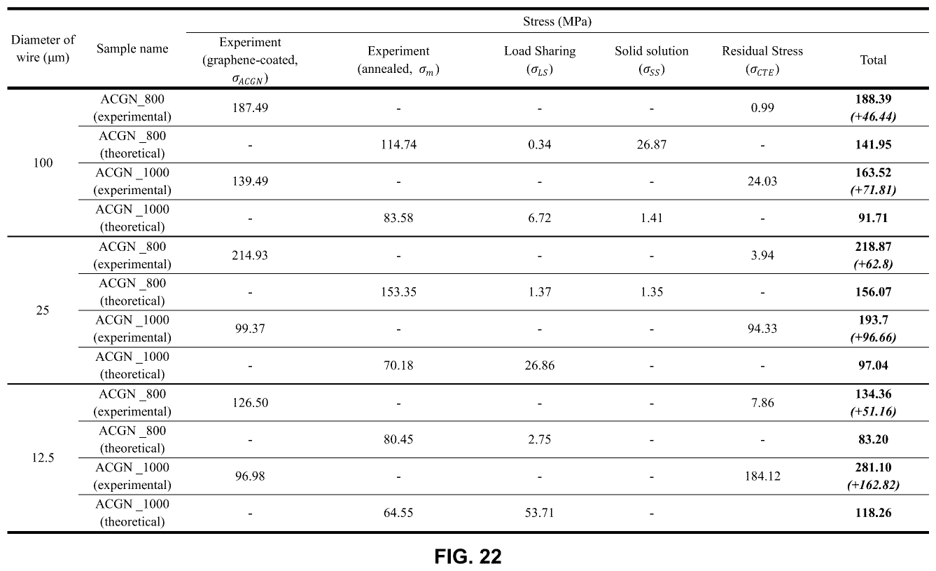

As a result, the residual stress of each wire with different thermal history or different diameter can be calculated and summarized in FIG. 22.

### True Strain

The true stress (σₜ) can be express like

$${σ}_{t} = \frac{F}{A}$$

where F is an applied force (or pressure) and A is an actual cross-sectional area that the force is applied. Considering the cylinder with constant volume (V=A₀l₀=Al, where V is a volume of cylinder, A₀ and l₀ an initial area and length, respectively, and l an final length), define σₜ can be defined like the right-hand side:

$${σ}_{t} = \frac{F}{A} = \frac{Fl}{{A}_{0} {l}_{0}} = {σ}_{eng} \frac{l}{{l}_{0}} = {σ}_{eng} ( 1 + {ε}_{eng} ) .$$

The true strain (εₜ) can be defined like

$${ε}_{t} = {\int }_{{l}_{0}}^{l} \frac{dl}{l} = ln ( \frac{l}{{l}_{0}} ) = ln ( 1 + {ε}_{eng} ) .$$

Based on the true stress and strain.

### Example 2

### ACGN Wires

In this example, the microstructure-property relation of ACGN wires is explored with an emphasis on graphene-enhanced mechanical properties. To quantify the effect of graphene on their mechanical properties, Ni wires were prepared and characterized with three different conditions: as-received, annealed (ANI), and graphene-coated (ACGN) wires. It is noted that annealed wires underwent the same thermal histories as their graphene-coated counterparts. Therefore, mechanical properties of the annealed and graphene-coated Ni wires with the same diameter were characterized and compared to each other to quantify mechanical enhancement directly associated with continuous graphene structures. Furthermore, wires with three different diameters (e.g., D_{w}=100, 25, and 12.5 μm) were used to investigate the effect of the wire-size-dependent mechanical properties (hereafter referred to as the size effect). Table 2 summarizes different types of wire samples prepared under different conditions and their naming convention. For example, 25_Ni_as-received, 25_ANi_800, and 25_ACGN_800 indicate three different types of 25-μm-diameter Ni wires, i.e., as-received, annealed at 800° C., and graphene-synthesized at 800° C., from left to right, respectively.

TABLE 2
Different types of wire samples based on their size, materials, and preparation
conditions. Note that the sample names (the first column) includes three parts
separated by “_”, namely, wire diameter, process/material type,
and process temperature. ACGN is axially bi-continuous graphene-nickel.
Letters “A” and “Ni” indicate “Annealing” and “Nickel”, respectively.

| | | Annealing condition | | | |
|---|---|---|---|---|---|
| | Wire | | | Flow of | |
| | diameter | Temperature | Time | benzene | |
| Sample name | (μm) | (° C.) | (min) | (sccm) | Description |
| 100_ACGN_800 | 100 | 800 | 10 | 10 | Mono- or bi-layer |
| | | | | | graphene |
| 100_ANi_800 | | 800 | 10 | — | No graphene |
| 100_ACGN_1000 | | 1000 | 10 | 20 | Multi-layer graphene |
| 100_ANi_1000 | | 1000 | 10 | — | No graphene |
| 25_ACGN_800 | 25 | 800 | 10 | 10 | Mono- or bi-layer |
| | | | | | graphene |
| 25_ANi_800 | | 800 | 10 | — | No graphene |
| 25_ACGN_1000 | | 1000 | 10 | 20 | Multi-layer graphene |
| 25_ANi_1000 | | 1000 | 10 | — | No graphene |
| 12.5_ACGN_800 | 12.5 | 800 | 10 | 10 | Mono- or bi-layer |
| | | | | | graphene |
| 12.5_ANi_800 | | 800 | 10 | — | No graphene |
| 12.5_ACGN_1000 | | 1000 | 10 | 20 | Multi-layer graphene |
| 12.5_ANi_1000 | | 1000 | 10 | — | No graphene |

### Characterization of Graphene Structures on Fine ACGN Wires

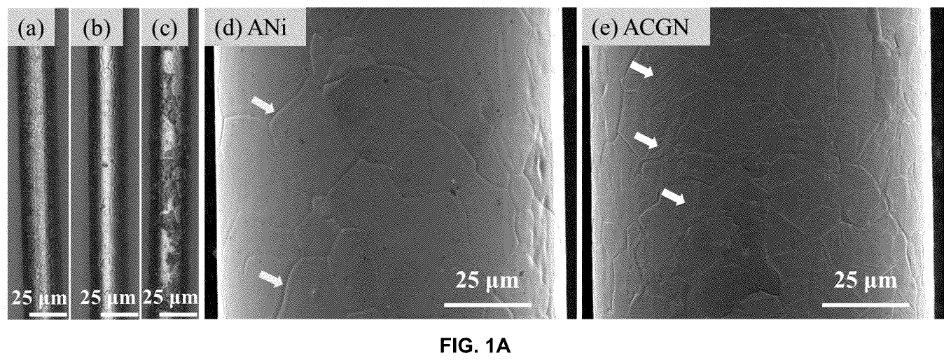

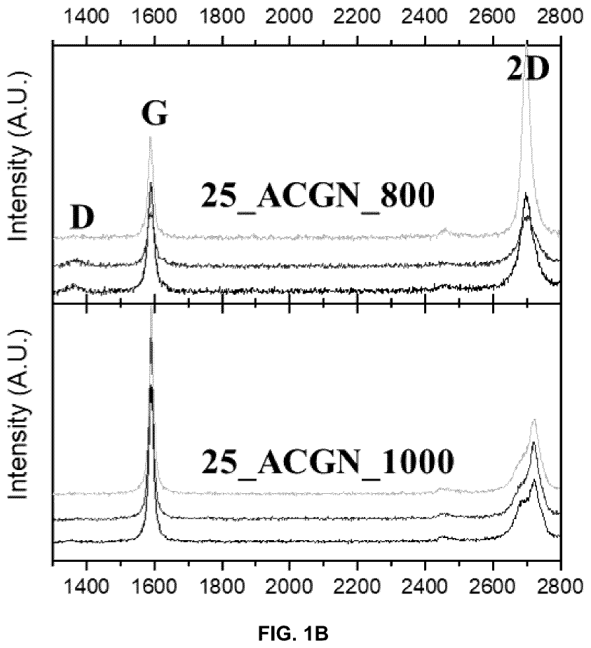

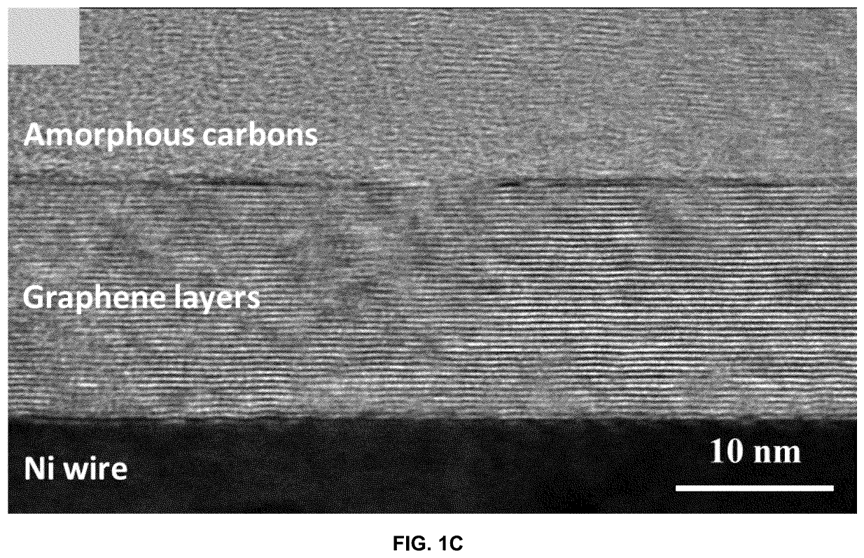

ACGN wires were fabricated using the CVD process described in the Materials and Methods section. This batch CVD process allows co-fabrication of tens of ACGN (or ANi) wires with three different diameters together in the same CVD (or annealing) furnace, respectively, and, therefore, can eliminate process-sensitive sample-to-sample variation. FIG. 1A at (a)-(c) show optical images of 25_Ni_as-received, 25_ANi_800, and 25_ACGN_800, respectively. Optical observation of 25_ANi_800 shows larger grains, compared to 25_Ni_as-received, due to thermally induced grain growth at 800° C. and clean surfaces without obvious contaminations. In contrast, 25_ACGN_800 exhibits areas with dark gray color likely associated with carbon structures formed on the wire surface. The high magnification scanning electron microscope (SEM) images of 100_ANi_1000 and 100_ACGN_1000 in FIG. 1A at (d)-(e) respectively, show somewhat different surface topography of each wire. 100_Ani_1000 has smooth surface profiles with clear grain boundaries as indicated by the arrows in FIG. 1A at (d). On the other hand, due to the discontinuity of crystal structure, the smaller grains of the graphene structures are observed on 100_ACGN_1000 wire, compared to the grain size of 100_Ani_1000 wire. And, wrinkles within the graphene structures can be seen in FIG. 1A at (e) (see arrows) likely due to the thermal expansion coefficient mismatch between graphene and metal catalyst.

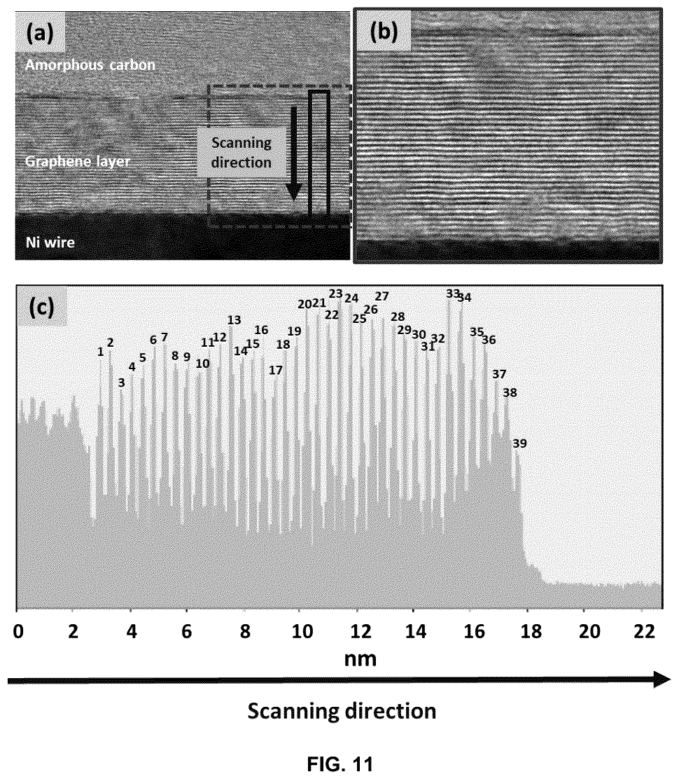

Raman analyses was conducted at multiple locations (more than ten times) on each ACGN wire immediately after CVD, and the representative Raman patterns of 25_ACGN_800 and 25_ACGN_1000 were shown in FIG. 1B. The results show 2D (˜2700 cm⁻¹) and G (˜1580 cm⁻¹) peaks for both 25_ACGN_800 and 25_ACGN_1000, confirming that the wires are indeed coated by graphene. Note that the relative intensities of 2D to G peaks, known as I_{2D}/I_{G} ratios, of ACGN depend on CVD temperatures as summarized in Table 3. For 25_ACGN_800, the full-width half maximum (FWHM) values of the 2D peaks are 28.40-56.91 cm⁻¹ and the I₂D/I_{G} ratio is 0.97-1.32. These Raman analyses indicate that the 25_ACGN_800 wires are coated by either mono- or bi-layers of graphene. The corresponding FWHM and I₂D/I_{G} values for 25_ACGN_1000 are >69.5 cm⁻¹ and 0.74-0.78, respectively, which are the key characteristics of multi-layered graphene. Additional transmission electron microscope (TEM) analysis was conducted for multilayered graphene structures because quantitative analysis, e.g., the exact number of graphene layers, becomes challenging using the Raman technology. The TEM image in FIG. 1C shows the cross section of 100_ACGN_1000 including a 100-μm-diameter Ni wire, graphene layers, and amorphous carbon from the bottom to the top of the image. The intensity profile of the TEM image (see FIG. 11) indicates that the Ni wire is coated by thirty-nine layers of graphene and each layer is separated by about 0.35 nm. In summary, microscale fine Ni wires were confirmed to be covered by either mono-/bi-layered graphene or tens of graphene layers when processed at 800° C. or 1000° C., respectively.

TABLE 3
Characteristics of Raman spectra for 25_ACGN_1000 and
25_ACGN_800 (see Table 2 for naming convention).

| | | Full-width half | | |
|---|---|---|---|---|
| | | maximum | | |
| Sample | Region | (FWHM) | I_{2D}/I_{G} | The number of graphene |
| 25_ACGN_800 | Point 1 | 56.91 | 0.99 | Bi-layer |
| | Point 2 | 45.35 | 0.97 | Bi-layer |
| | Point 3 | 28.40 | 1.32 | Mono- or bi-layer |
| 25_ACGN_1000 | Point 1 | 74.54 | 0.74 | Multi-layer |
| | Point 2 | 69.51 | 0.77 | Multi-layer |
| | Point 3 | 76.20 | 0.78 | Multi-layer |

### Mechanical Properties of ACGN Wires

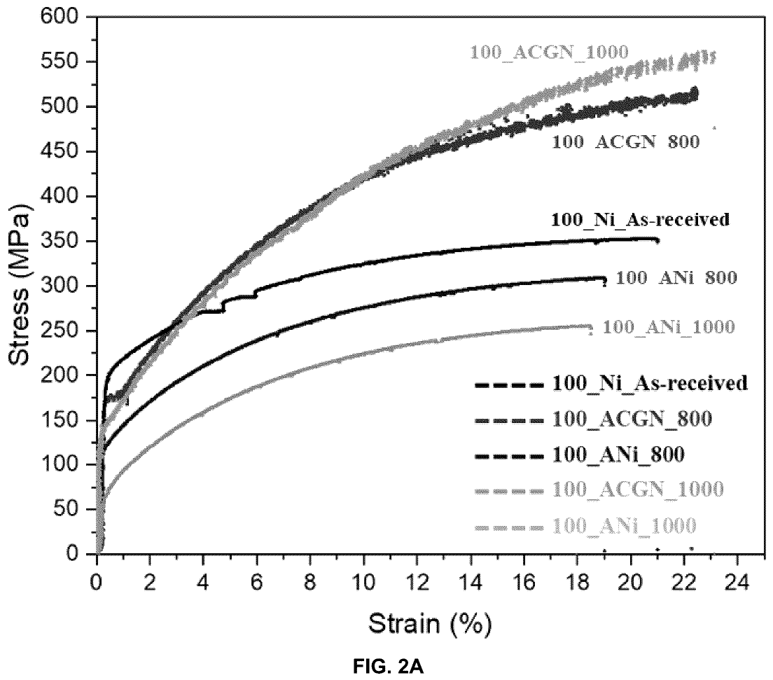

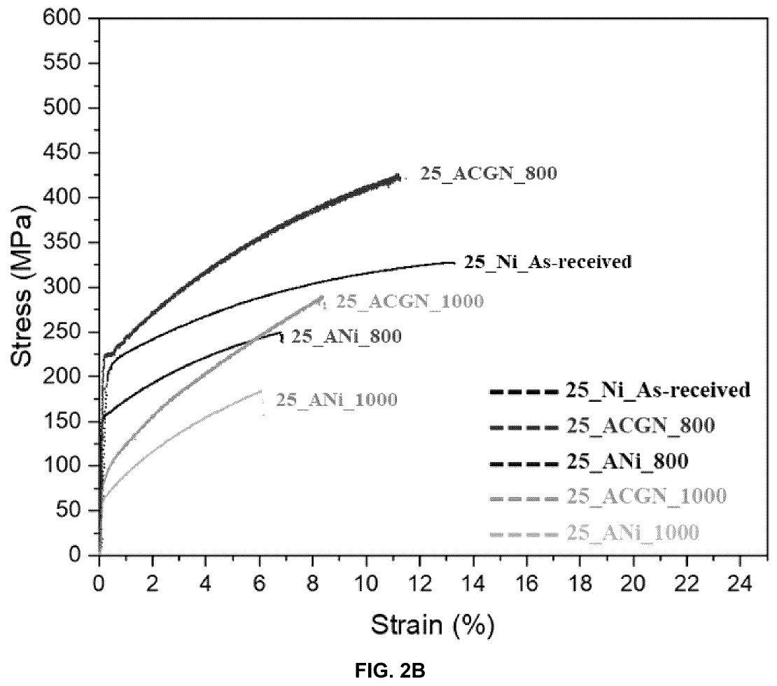

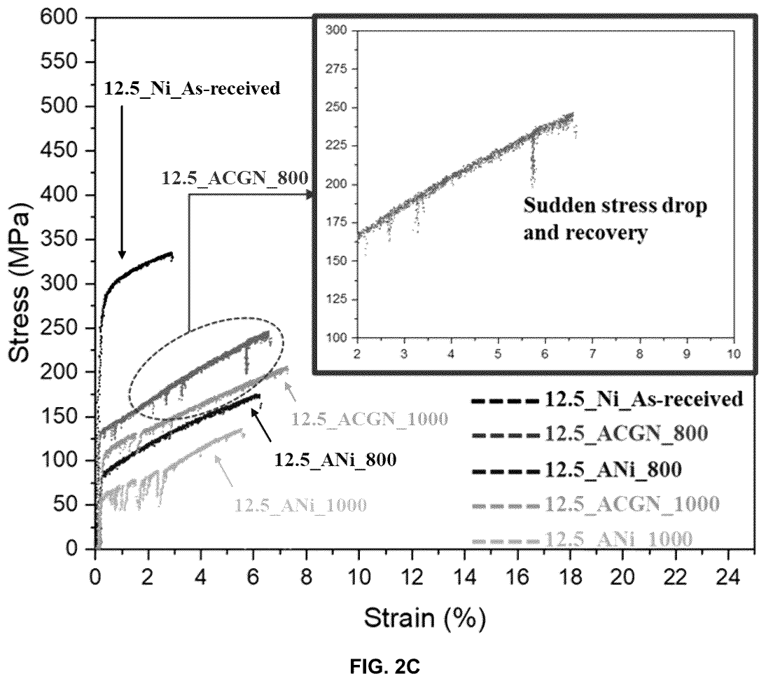

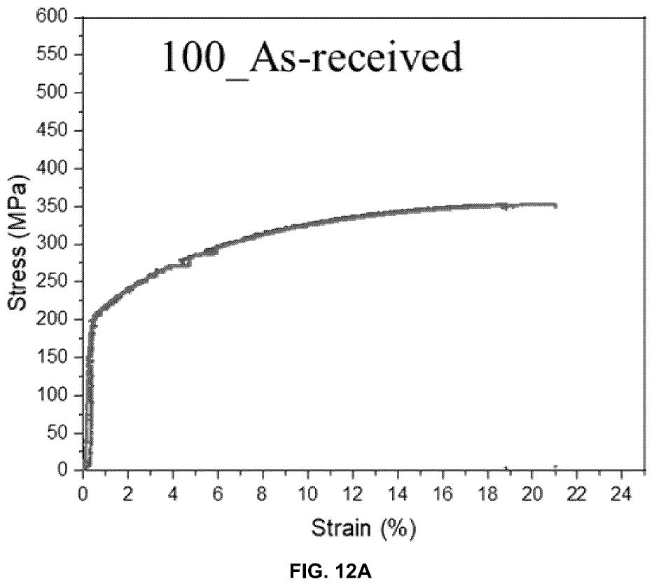

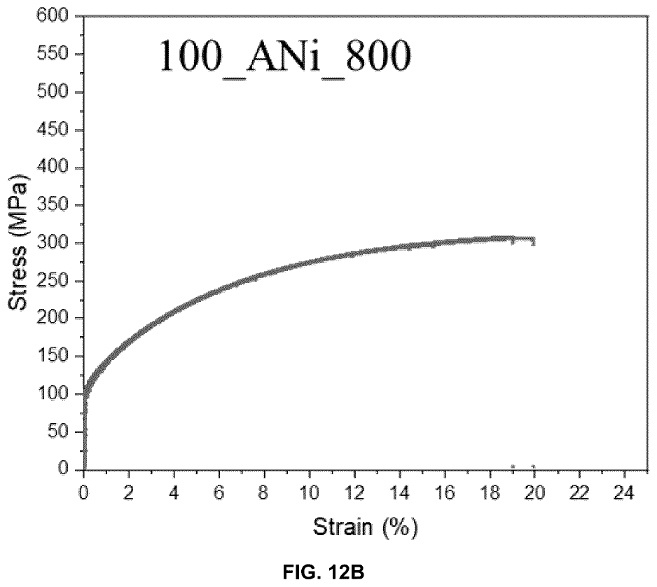

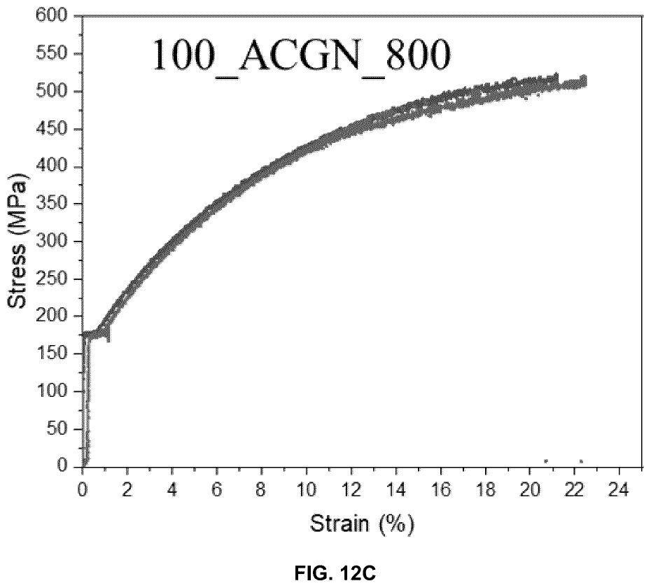

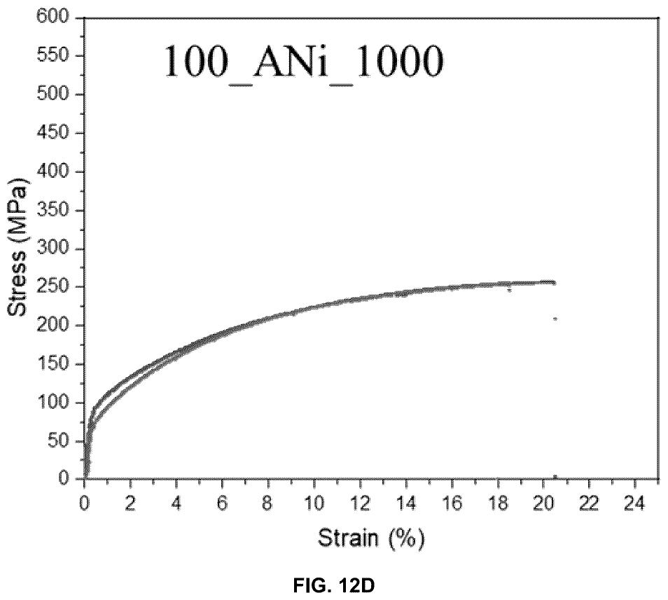

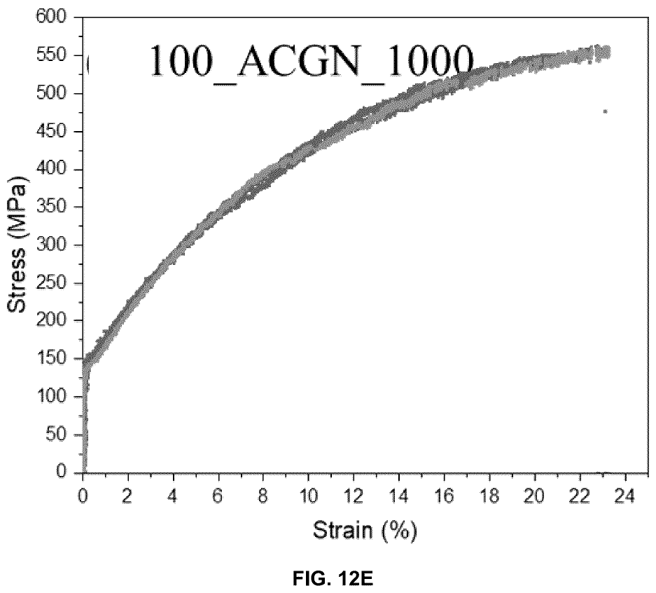

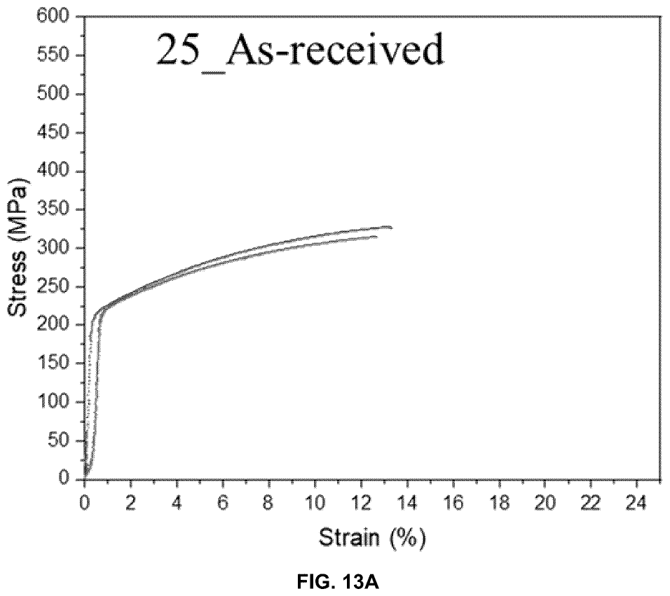

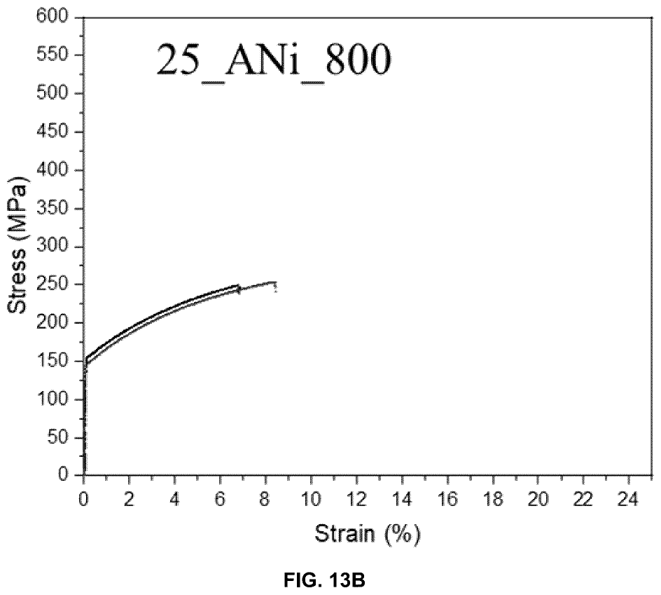

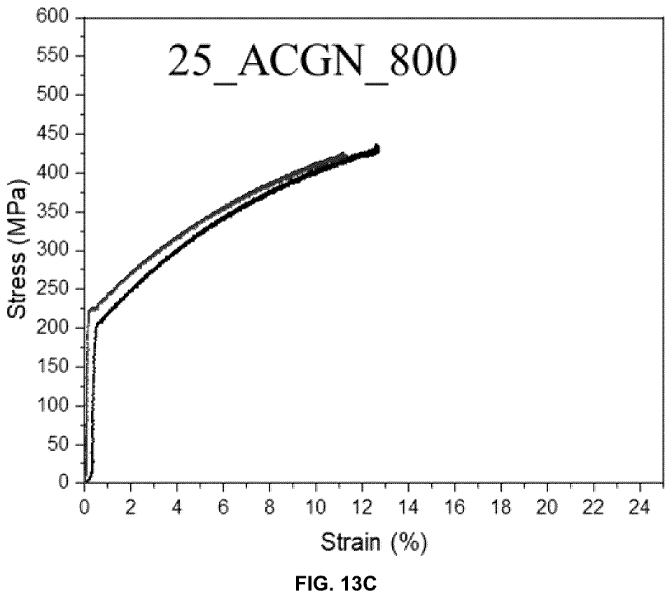

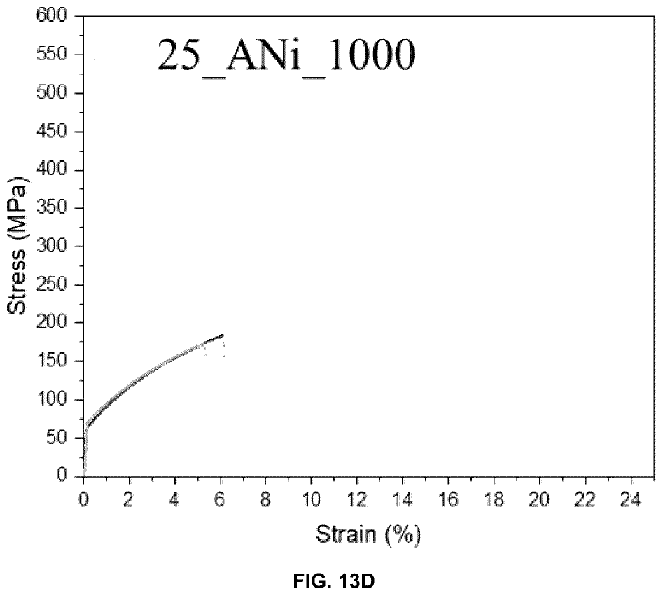

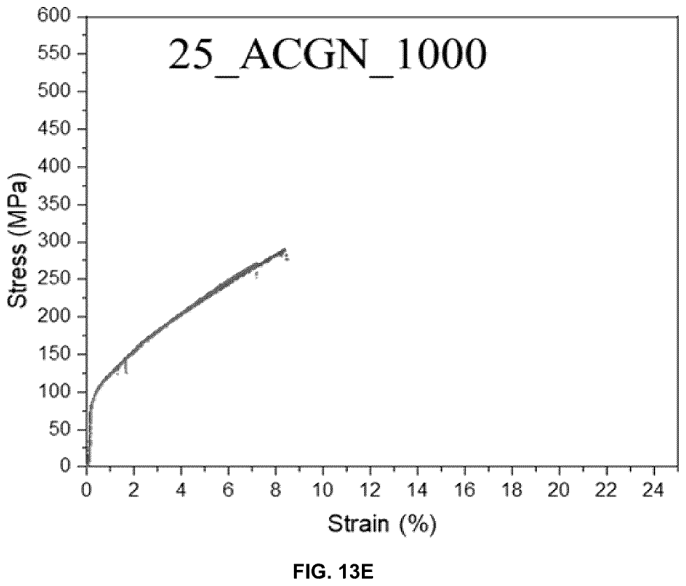

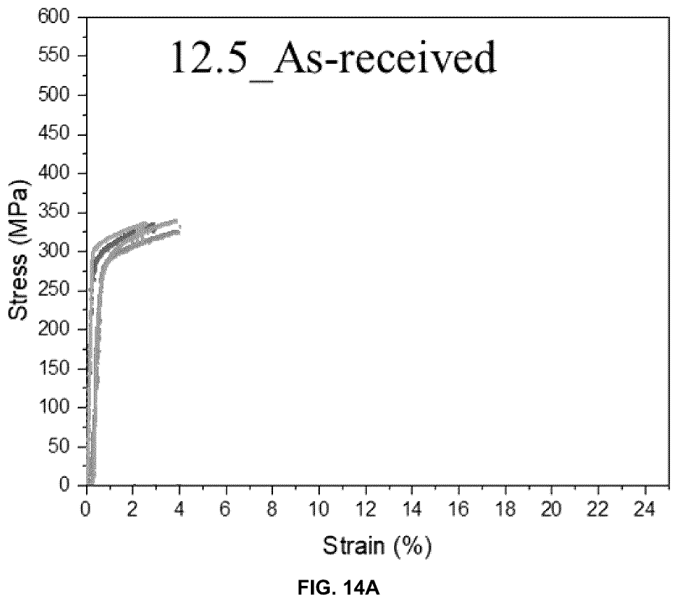

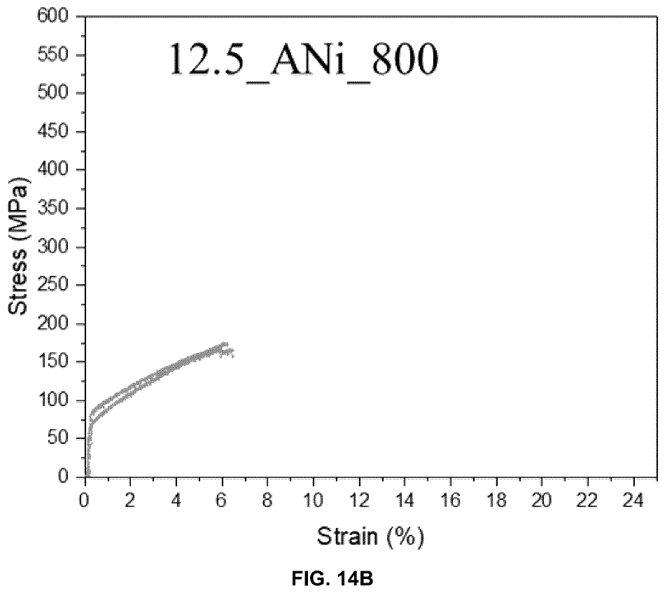

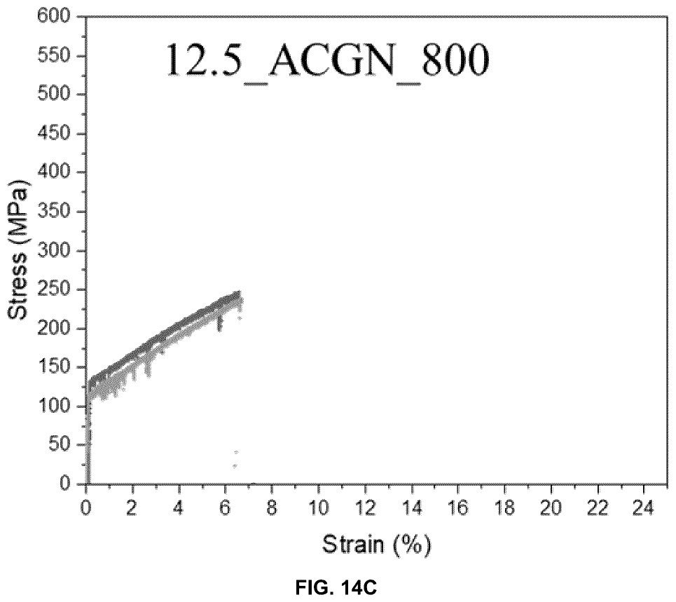

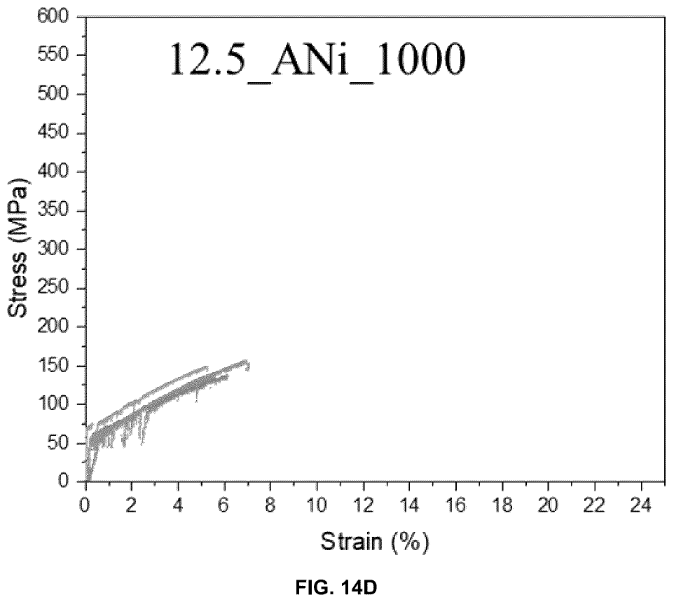

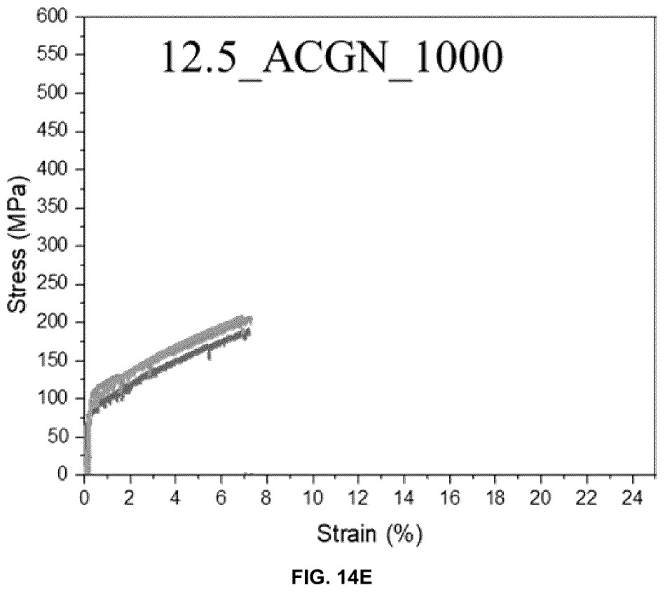

Here, the focus is twofold: mechanical characterization of graphene-enhanced fine wires and the underlying mechanism(s) for mechanical enhancement. FIG. 2A, FIG. 2B, and FIG. 2C shows stress-strain curves of different types of fine Ni wires, obtained by a custom-built uniaxial tensile tester. For clarification, at least two independent test results for each wire type are tested, and the representative curves are presented in the FIG. 2A, FIG. 2B, and FIG. 2C (see FIG. 12A, FIG. 12B, FIG. 12C, FIG. 12D, FIG. 12E, FIG. 13A, FIG. 13B, FIG. 13C, FIG. 13D, FIG. 13E, FIG. 14A, FIG. 14B, FIG. 14C, FIG. 14D, and FIG. 14E) for all stress-strain curves of Ni wires). Toward the validation of our experimental setup, it is worth mentioning two experimental observations: (1) experimentally obtained mechanical properties of as-received Ni wires in (Table 2) match well with their expected properties from the vendors and (2) the multiple strain-stress curves of each wire type from individual wires are consistent with each other. As an example of the second observation, FIG. 12A shows that two 100_Ni_As-received wires follow a nearly identical stress-strain relation.

Interestingly, mechanical responses of as-received Ni wires depend on their diameters, e.g., the yield strength increases and the maximum elongation with decreasing wire diameter, respectively. This is likely manufacturing-process-dependent material properties, i.e., the smaller wires undergo more severe plastic deformation and, as a result, effectively stronger and more brittle compared to their larger counterparts. This result can be evidenced by grain size reduction, e.g., d=6.30, 2.99, and 2.94 μm for D_{w}=100, 25, and 12.5, respectively (see Table 1).

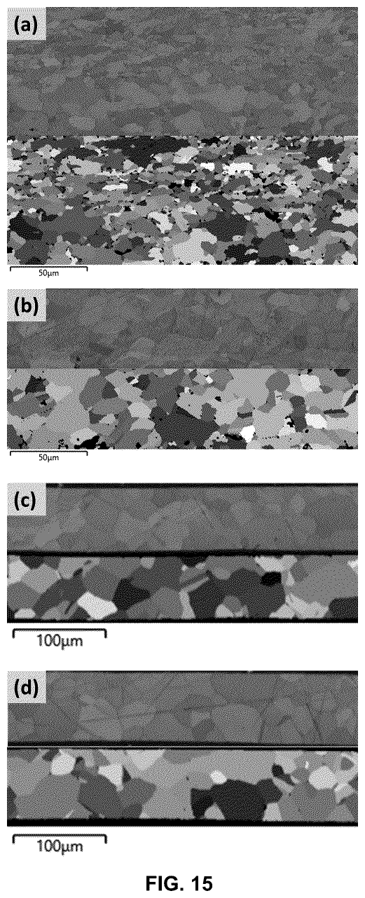

Because of these size- and temperature-dependent material behaviors of pure Ni wires, quantitative characterization of mechanical enhancement directly associated with graphene becomes non-trivial. To overcome this challenge, the stress-strain relations of graphene-coated Ni wires (ACGN) were obtained and compared to their corresponding annealed Ni wires (ANi). To clarify, the corresponding ANi wire, unless indicated otherwise, indicates a control pure Ni wire that has the same diameter and undergoes the same thermal history as the compared ACGN wire. This comparison study minimizes differences in Ni diameter and grain size between the compared pair and, therefore, allows unambiguous quantification of graphene-enhanced mechanical properties without the effects of wire diameter (i.e., size effect) and thermally induced microstructural changes (e.g., the Hall-Petch effect), respectively. For the latter, note that CVD temperature itself (800-1000° C.), even without graphene, can alter mechanical responses of Ni, e.g., via thermally activated grain growth and thermal annihilation of preexisting dislocations. For example, a more pronounced decrease of yield and ultimate tensile strengths was observed after annealing at higher temperatures. More specifically, 100_Ni_As-received, 100_ANi_800, and 100_ANi_1000 have different average grain sizes, i.e., 6.30, 10.11, and 21.69 μm (see EBSD analysis, FIG. 15 at (a)-(c)), and yield at different stresses, i.e., 205.18, 103.10, and 81.13 MPa, respectively. These experimental results can be explained by the Hall-Petch relation,

$${σ}_{y} = {σ}_{0} + \frac{{k}_{y}}{\sqrt{d}} ,$$

where σ_{y} is the yield strength, σ₀ is the lattice resistance, k_{y} is a strength coefficient, and d is average grain size.

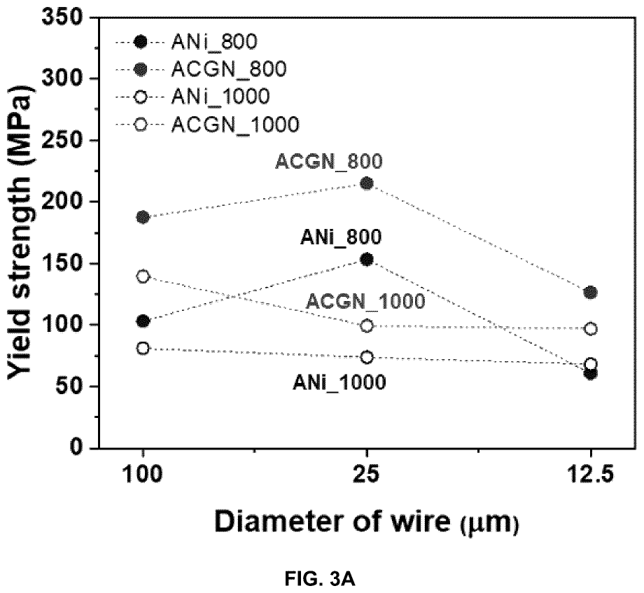

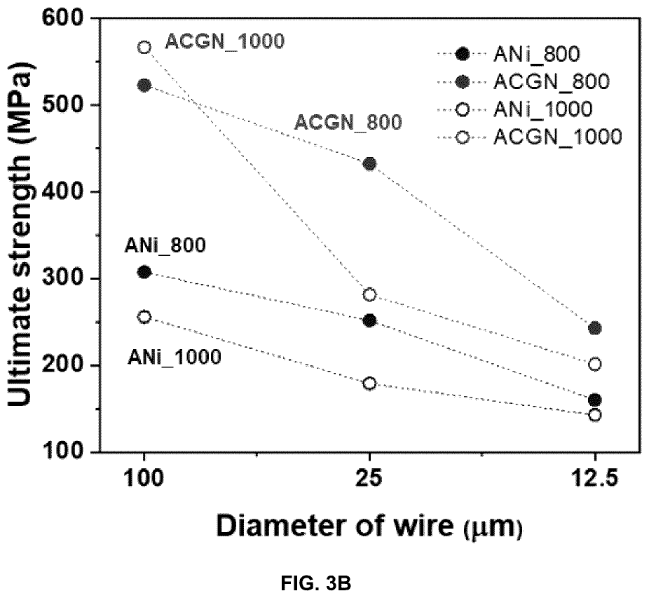

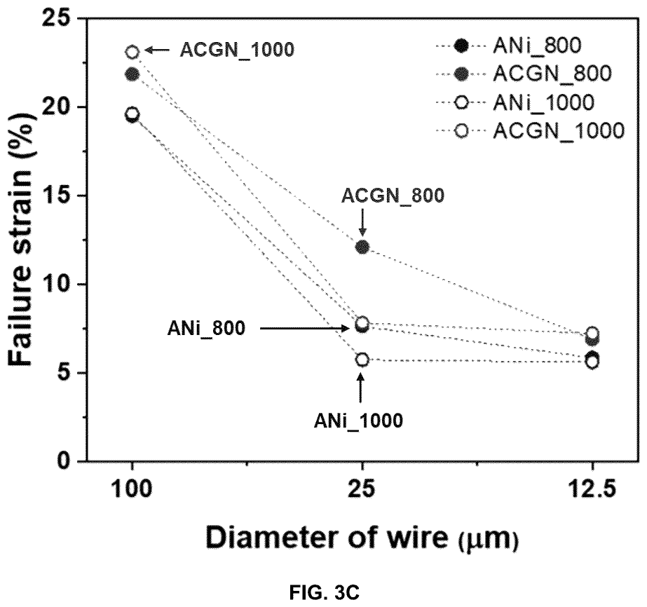

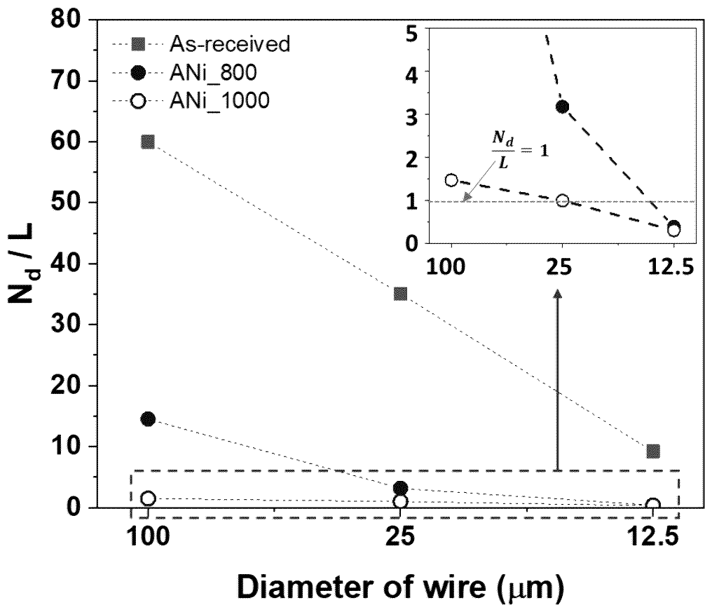

For direct comparison of the ACGN and ANi wire pairs, their yield strength (σ_{y}) (FIG. 3A), ultimate strength (σᵤ) (FIG. 3B), failure strain (ε_{f}) (FIG. 3C), and the number of grains (N_{d}) per wire length (L) for different wire diameter (D_{w}) (FIG. 8) are shown. In brief, the results present both hypothesized and unexpected results. The former is that graphene-coated Ni wires are mechanically superior, including higher yield/ultimate strength and more pronounced work hardening compared to their annealed counterparts. These trends, observed for all three diameters and two CVD temperatures, are expected considering ultimate tensile strength (130 GPa) and Young's modulus (1000 GPa) of graphene and known graphene-dislocation interplays, e.g., graphene acts as barriers against dislocation motion and suppress dislocation escape to free surfaces. It is worth noting that work hardening rates for 12.5-μm-diameter ACGN and ANi are somewhat similar to each other, compared to the pronounced differences for larger wires.

To be more specific, consider yield and ultimate strengths in FIG. 2A and FIG. 2B. 100_ACGN_800 and _1000 offer considerably improved σ_{y} and σᵤ compared to 100_ANi_800 and _1000, respectively, for example, σ_{y}=187.50 MPa and σᵤ=522.55 MPa for 100_ACGN_800, about 81.9% and 70.1% higher, respectively, compared to 100_ANi_800. The graphene-coated 25- and 12.5-μm-diameter wires also show a qualitatively similar trend, e.g., σ_{y}=214.93 MPa and σᵤ=431.92 for 25_ACGN_800 compared to σ_{y}=153.35 MPa and σᵤ=251.46 for 25_ANi_800, while σ_{y}=126.50 MPa and σᵤ=242.52 MPa for 12.5_ACGN 800 compared to σ_{y}=80.45 MPa and σᵤ=172.00 MPa for 12.5_ANi_800. In addition, the approach, i.e., ACGN, integrates axially bi-continuous graphene-metal composite wires and, hence, the failure of ACGN is likely dominated by post-yield behavior of Ni. One interesting observation is that ductility of ACGN, evaluated by failure strain, is even higher than ANi.

Yield strength (σ_y) of ACGN wires in FIG. 3A also shows two unexpected results: (1) ACGN wires processed at 800° C. (ACGN_800), despite the fewer number of graphene layers (see Table 2), are consistently stronger than ACGN wires processed at 1000° C. (ACGN_1000) and (2) ACGN wires, unlike as-received wires, do not follow the well-established “smaller is stronger” trend for micro/nano-scale materials, e.g., 25_ACGN_800 offers higher yield strength than both 12.5_and 100_ACGN_800. It is worth emphasizing that the second point is somewhat counter-intuitive because a graphene-to-nickel volume ratio, for the given number of graphene layers, increases with the reduction of wire diameter and, therefore, an increased contribution directly from ultra strong graphene structures is likely expected. These unexpected results may be explained by microstructural changes in Ni with the reduction of wire diameter and, subsequently, by different graphene-nickel interplay.

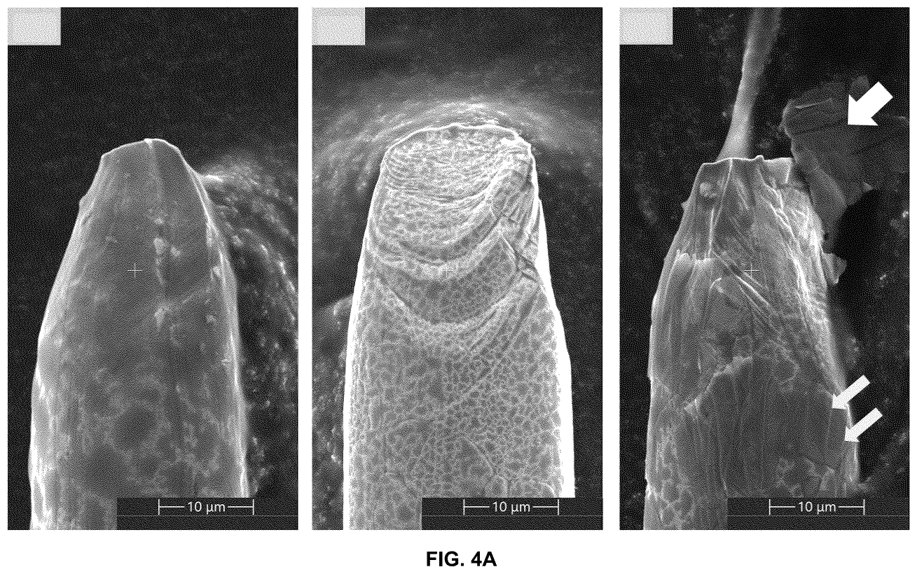

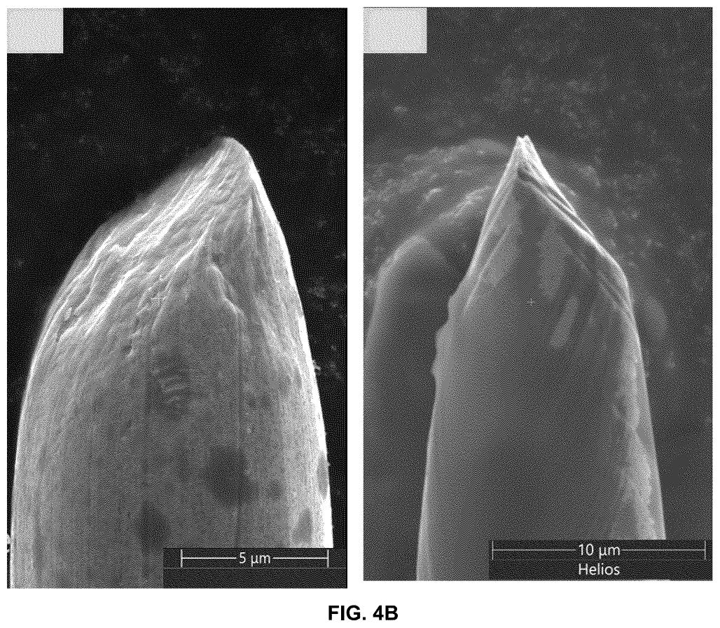

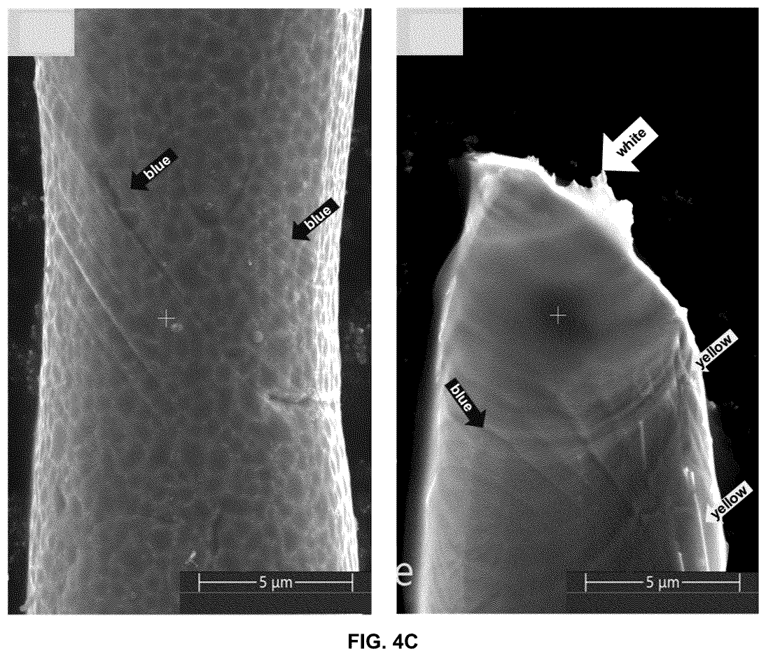

FIG. 4A, FIG. 4B, and FIG. 4C show SEM images of different types of Ni wires after completion of each mechanical testing for 25- and 12.5-μm-diameter wires (top and bottom rows, respectively). For 25-μm-diameter wires (see the first row), the ACGN wire in FIG. 4A at (c) shows distinctive features, compared to pure Ni counterparts, including delamination of a graphene layer (see the white arrow near the failed surface) and formation of the wrinkles in the graphene structure (see the yellow arrows). These different observations are likely due to the elastic-plastic strain mismatch between graphene and nickel, i.e., the Ni wire undergoes large plastic deformation while graphene deforms mainly elastically. For 25-μm-diameter wires (see the second row), the pure Ni wires-as-received and annealed wires in FIG. 4B at (d) and FIG. 4B at (e), respectively-show a typical fracture surface of a ductile metal. One unique observation is multiple slip bands near the fracture tip (FIG. 4B at (e), respectively) as well as in the middle of the wire (see the blue arrows in FIG. 4C at (f)). The observed slip bands across the entire wire diameter may offer a reasonable explanation for sudden stress drops in the stress-strain curves for the 12.5-μm-diameter wires, e.g., see the inset in FIG. 2C. For ACGN in FIG. 4C at (g), overhanging graphene structures (see the white arrow) and wrinkles (see the yellow arrows) in graphene can be seen near the necking region.

### Discussion

In the previous section, mechanical properties of the axially bi-continuous graphene-nickel (ACGN) wires were quantified and demonstrated their enhanced mechanical properties compared to their annealed Ni counterparts (ANI). In addition, the size effect—mechanical response that depends on wire diameter—has been explored by characterizing Ni wires with three different diameters, i.e., D_{w}=100, 25, and 12.5 μm. In this section, the beneficial combined strength and ductility of ACGN is directly compared to the other graphene-metal composites previously reported in the literature. It is then theoretically considered how the microstructural features of the ACGN wires govern their mechanical properties, such as yield, ultimate tensile strength, and failure strain.

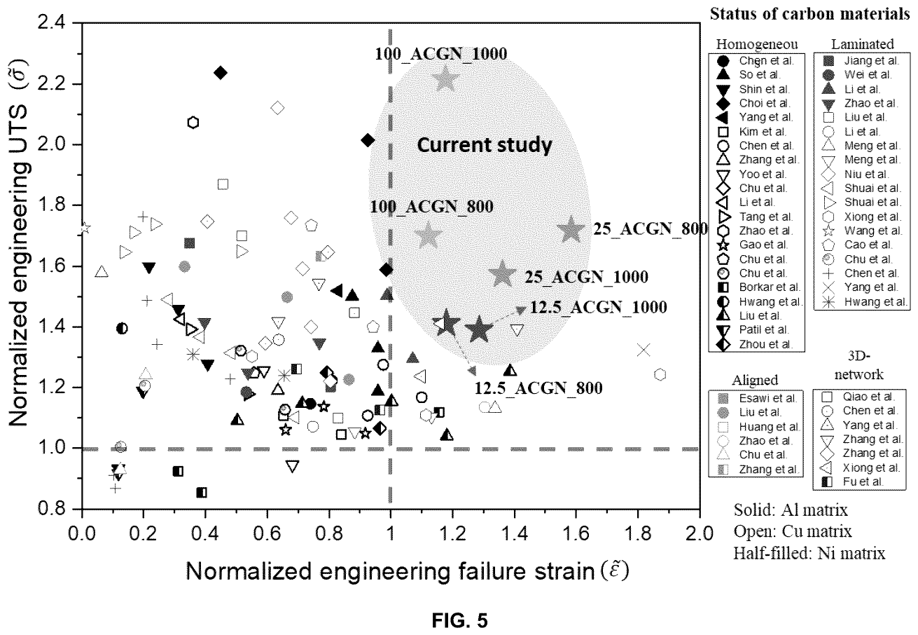

Breaking the intrinsic strength-ductility relation: Experimental results indicate that ACGN wires exhibit significantly enhanced mechanical performance without comprising their ductility, all compared to their annealed counterparts. To compare the beneficial combined strength-ductility performance of ACGN against the existing carbon-enhanced metal matrix composites (CMMCs), a literature review is summarized in FIG. 5. All references are categorized based on two criteria. First, copper, aluminum, and nickel (see open, solid, half-filled markers, respectively) are chosen because they are common metal matrices. Second, CMMCs are grouped into homogeneous dispersion, lamination, alignment, and 3D-network (indicated by black, green, orange, and blue color, respectively) based on their specific architectural features. The results of ACGN are designated by red solid stars near the top-right corner, highlighted by the yellow area. Ultimate tensile strength and the failure strain of all CMMCs are normalized by those of the corresponding pure metal matrix (\tilde{σ} and \tilde{ε}, respectively) to quantitatively compare their mechanical performance. For clarification, \tilde{σ}=1 and \tilde{ε}=1 correspond to the ultimate tensile strength and the failure strain of a metal matrix itself, respectively.

It is easy to notice that the current state-of-the-art CMMCs, regardless of a choice of a metal matrix and graphene-metal architecture, shows a strong trade-off between the strength and ductility, evidenced by both the empty top-right corner (except ACGN) and densely populated data within the top-left area defined by \tilde{σ}1 and \tilde{ε}<1. On the contrary, ACGN offers both enhanced mechanical strength and excellent ductility and shows a different \tilde{σ}-\tilde{ε} trend, compared to other CMMCs, that clearly breaks the trade-off condition. It was hypothesized, without being bound by any particular theory, that this extraordinary, combined strength-ductility is due to the unique axially bi-continuous structures of ACGN.

Yield stress: In conventional CMMCs, small scale carbon materials are dispersed in a much larger metal matrix and, as a result, data interpretation and modeling of their mechanical responses become complex. For example, several mechanisms are concurrently activated in CMMCs, including load transfer strengthening (Δσ_{LT}), solid solution strengthening (Δσ_{SS}), thermal mismatch (Δσ_{CTE}), Orowan strengthening (Δσ_{Orw}), and grain refinement (Δσ_{HP}). As a result, yield strength of CMMCs (σ_{CMMC}) is often expressed by:

$${σ}_{CMMC} = {σ}_{m} + Δ {σ}_{LT} + Δ {σ}_{SS} + Δ {σ}_{CTE} + Δ {σ}_{Orw} + Δ {σ}_{HP} \qquad ( Eq . 1 )$$

where σ_m is yield strength of a metal matrix. Due to the complex coupling of these mechanisms, there is still a large discrepancy between experimental results and theoretical predictions in the literature, especially when a volume fraction of carbon materials in CMMC is relatively high, e.g., above 4 vol. % of carbon materials.

It is worth noting that ACGN, compared to conventional CMMCs, offers attractive features in mechanical analysis and theoretical modeling due to its simple bi-continuous shell-core structure and simple uniaxial loading condition. For example, it is reasonable to assume homogeneous graphene distribution, an identical graphene-nickel (hereafter mGr-Ni) interface along the length direction of ACGN, as well as direct load sharing (Δσ_{LS}) between Ni and mGr at any given cross section. Due to the unique bi-continuous structure, it can be also argued that the Orowan strengthening (Δσ_{Orw}) and effective grain refinement (Δσ_{HP}), which rely on graphene-metal interplay within a metal matrix, can be negligible in ACGN because its graphene structure is continuous and located at the outer surface of each Ni wire. In addition, dislocations in ACGN will likely pile up against the continuous graphene structures along the graphene-nickel interface. Therefore, it is reasonable to assume that the strong graphene structures will passivate the free surface of Ni, prevent dislocation escapes, and increase resistance against subsequent dislocation motion. Hereafter Δσ_{GN} designates the combined effect of these mechanisms at the graphene-nickel interface. Based on the arguments above, the yield strength of ACGN (ϕ_{ACGN}), by modifying Eq. 1, can be written as:

$${σ}_{ACGN} = {σ}_{m} + Δ {σ}_{LS} + Δ {σ}_{SS} + Δ {σ}_{CTE} + Δ {σ}_{GN} \qquad ( Eq . 2 )$$

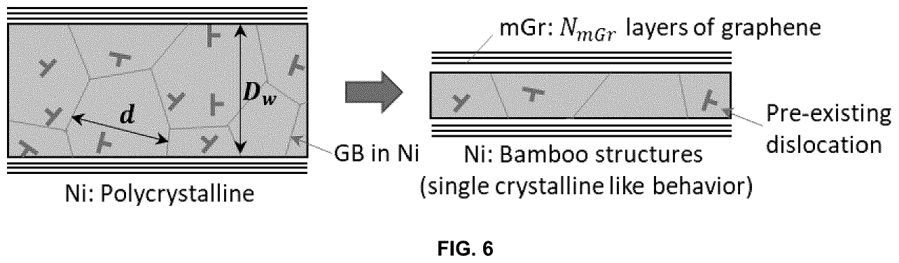

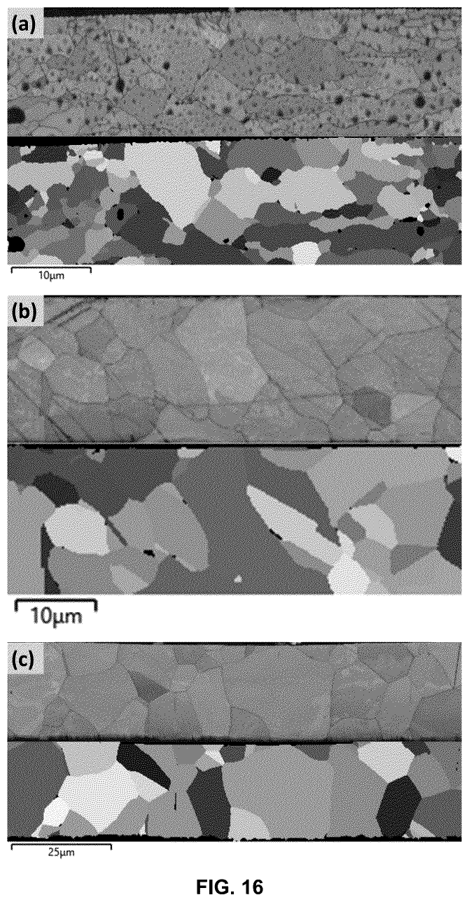

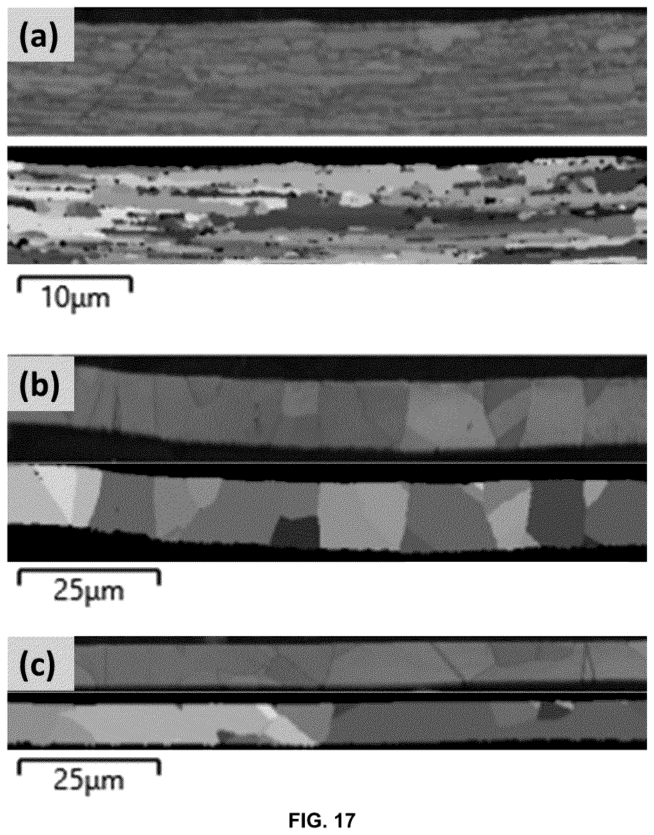

To further emphasize the importance of Δσ_{GN}, it can be shown that the graphene-nickel interface becomes more relevant with reduction of wire diameter. The size dependent mechanical response of ACGN can be triggered by several different mechanisms, including the microstructural transition from poly- to single-crystalline in Ni, material deformation accommodated by preexisting dislocations vs dislocation nucleation, bulk- to surface-dominant deformation mechanisms, an increase in graphene-to-nickel volume fraction, and/or their coupling, with reduction of wire diameter. To provide details, consider ACGN in FIG. 6 with the average grain size d, wire length L, and diameter D_{w} of Ni, respectively. Using the given dimensions and geometry of ACGN, it is simple to show that the number of grains (N_{d}) in the Ni wire can be estimated by

$${N}_{d} = \frac{{V}_{W}}{{V}_{d}} = \frac{3 L}{2 d} {( \frac{{D}_{w}}{d} )}^{2} \qquad ( Eq . 3 )$$

where V_{w}=Lπ(D_{w}/2)² and V_{d}≈π(d)³/6 are the volumes of the wire and the average grain, respectively. Note that the number of grains per wire length (N_{d}/L) is proportional D_{w}², indicating the number of grains within the cross-section of the Ni wire will decrease from multiple grains to a single grain as D_{w} decreases with respect to d. For example, FIG. 6 illustrates a decrease in N_{d}/L from (left) larger to (right) smaller wires. Obviously, N_{d}/L<1 indicates a single grain in the entire wire cross section likely with elongated shape in the wire length (or axially) direction. Note that this trend is experimentally validated by EBSD analyses shown in FIG. 15, FIG. 16, and FIG. 17.

Now why the effect of the mGr-Ni interface in ACGN becomes increasingly important for smaller D_{w} can be discussed by comparing the surface ratio of the mGr-Ni interface (A_{mgr-Ni}) to the total surface area (A_{Tot}) of individual grains in Ni. For the simplicity, the surface area of each average grain was approximated by using A_{d}≈πd² and then, the surface ratio can be written as following:

$$\frac{{A}_{mgr - Ni}}{{A}_{Tot}} = \frac{{LD}_{W} π}{{N}_{d} {A}_{d}} = \frac{2}{3} ( \frac{d}{{D}_{w}} ) \qquad ( Eq . 4 )$$

Eq. 4 suggests that the mGr-Ni interface will become dominant as D_{w} decreases with respect to d. Lastly, assuming the thickness of mGr (t_{mGr}) is much smaller than D_{w}, a graphene-to-nickel volume fraction (V_{mGr}/V_{w}) can be approximated by t_{mGr}/D_{w}. For a given t_{mGr}, the volume faction increases for a smaller wire and, hence, the direct contribution of graphene will be larger. In the following analysis, Δσ_{LS}, Δσ_{SS}, and Δσ_{CTE} were theoretically obtained in order to estimate Δσ_{GN} using Eq. 2.

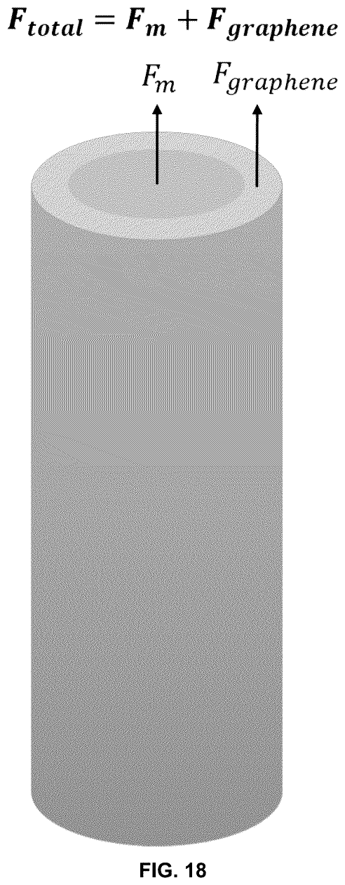

The load sharing strengthening (σ_{LS}) in ACGN, owing to its simple structure and directly load sharing between graphene and nickel under uniaxial loading, can be written as:

$${σ}_{LS} = {σ}_{m} {V}_{m} + {σ}_{gra} {V}_{gra} \qquad ( Eq . 5 )$$

where σₘ and σ_{gra} are the strengths of the matrix and graphene, respectively, and Vₘ and V_{gr} are their volume fractions, respectively (see FIG. 18). It is worth noting that Eq. 5 is much simpler compared to the shear-lag model, often used for conventional CMMCs. One common challenge in both the shear-lag model and Eq. 5 is to obtain accurate σ_{gra} for CVD grown graphene structures. Unlike micro/nanoscale graphene with intrinsic strength of about 130 GPa, grain boundaries (strength: 103 GPa), synthesis-process-dependent detects (strength: 16.4-45.4 GPa), and wrinkled graphene structures (strength: 12-60 GPa) are unavailable in macroscopic CVD grown graphene. Based on the previously reported strength of CVD grown graphene, it was assumed that σ_{gra} of ACGN is mainly bounded by the wrinkled structures, which were observed in ACGN regardless of its diameter, and, thus, σ_{gra}=12.57 GPa is used in the following analysis of the load sharing strengthening.

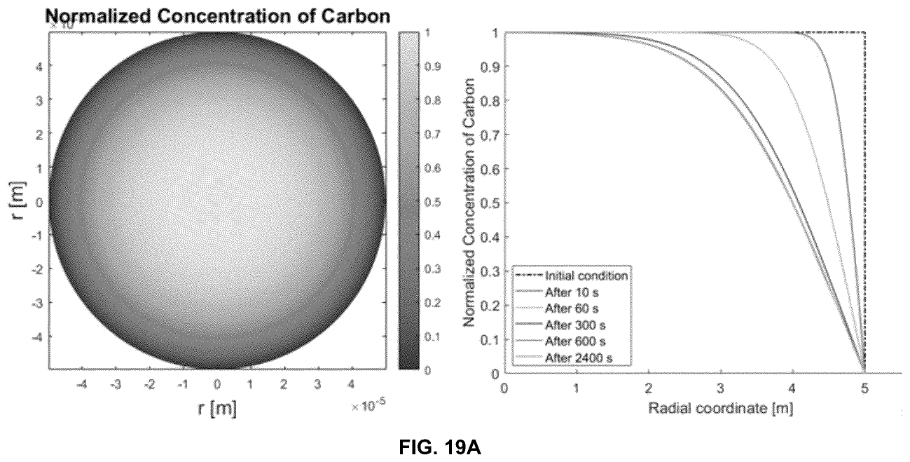

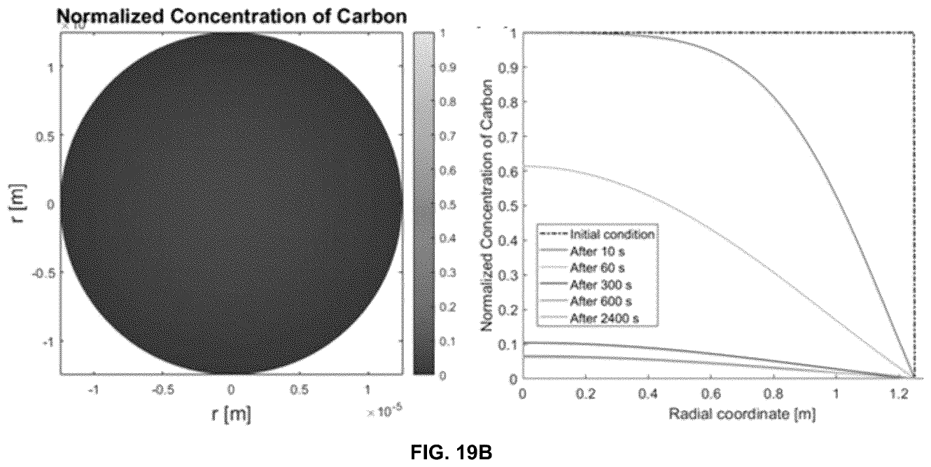

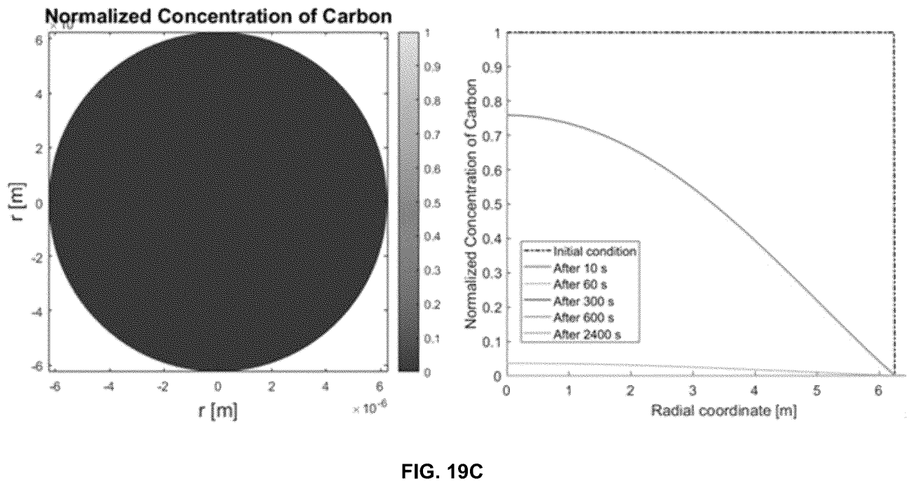

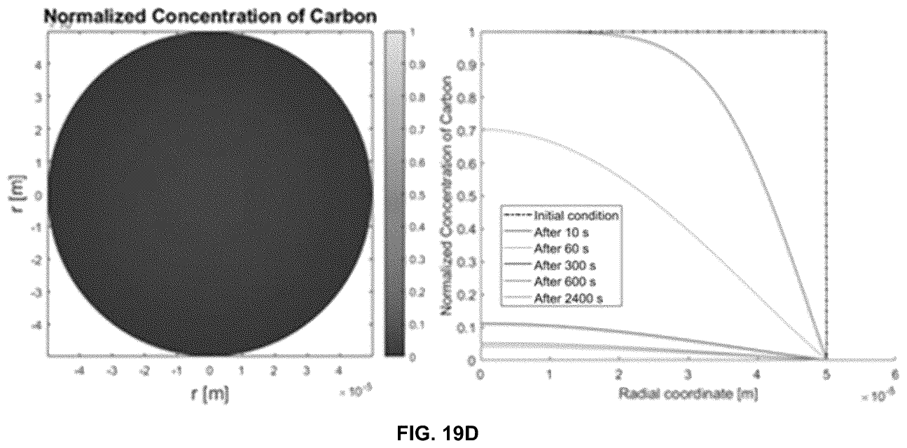

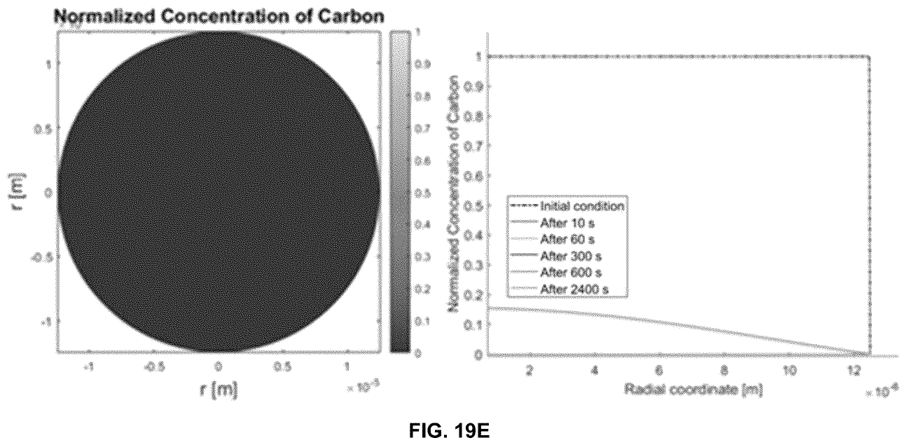

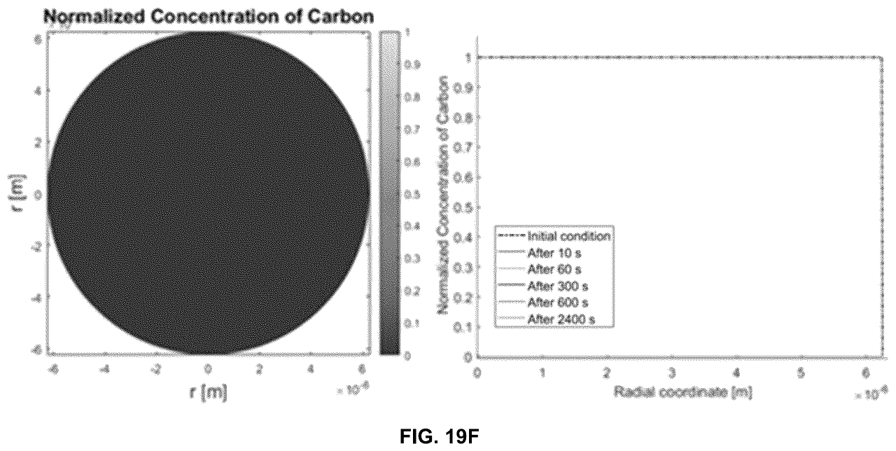

The solid solution strengthening (Δσ_{SS}) is also considered because (1) carbon solubility in Ni, while still limited compared to other metals, is not negligible (around 2.7 at. % carbon at 1326° C.) and (2) the synthesis mechanism of graphene on the surface of metal involves diffusion of carbon atoms into Ni. With residual carbon atoms in Ni, the solid solution strengthening (Δσ_{SS}) can be written as:

$$Δ {σ}_{ss} = {k}_{s} c \qquad ( Eq . 6 )$$

where kₛ is a constant (kₛ=G/10 where G is a shear modulus of metal) and c is atomic fraction of solution atom, i.e., carbon in nickel. To estimate c values in ACGN, numerical simulation was performed. The details on the simulation procedure and results are described in FIG. 19A, FIG. 19B, FIG. 19C, FIG. 19D, FIG. 19E, and FIG. 19F.

Thermally induced residual stress (Δσ_{CTE}) in ACGN is also relevant because (1) CVD graphene growth involves high temperature process and (2) coefficients of thermal expansion are significantly different for graphene (−3.4*10⁻⁶/K) and Ni (13*10⁻⁶/K). In the following analysis, it was assumed that ACGN is fully relaxed, i.e., no internal stress, when the axially continuous graphene structure just forms on a fine Ni wire at a CVD temperature (either T=800° C. or 1000° C.). After completion of cooling to room temperature, compressive and tensile stresses develop in graphene and Ni, respectively. It is important to remind that (1) the mGr-to-Ni volume fraction in ACGN is very small (0.0028%-0.43%) and (2) graphene yields at orders of magnitude higher stress than Ni. Because of these, the yield behavior of ACGN is likely dominated by a burst of dislocation activities within a Ni wire. Under tensile residual stress in Ni, the apparent yield strength of a Ni wire can be lower than its actual yield strength during mechanical characterization. To take this into account, the residual stress (Δσ_{CTE}) in Ni was calculated based on the well-defined structures of ACGN (FIG. 20).

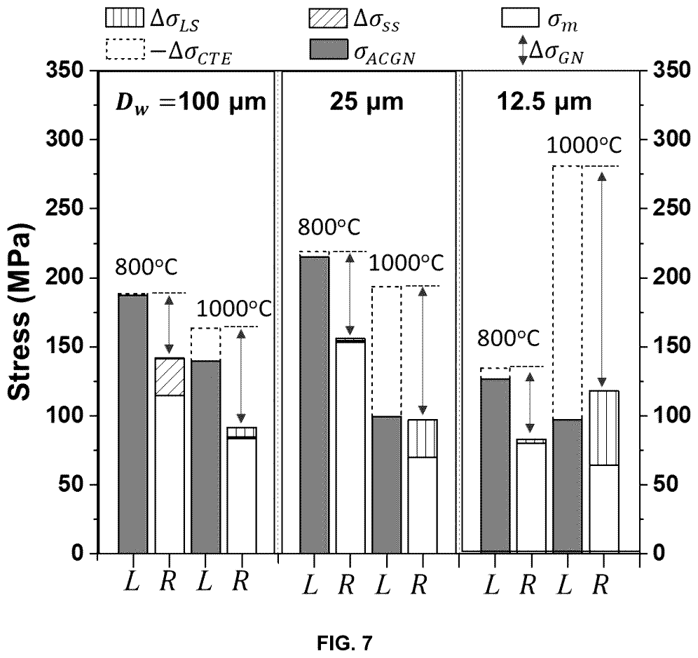

Following described approaches above, the value of each term in Eq. (2) was obtained through experiments (σ_{ACGN} and σₘ) and theoretical analyses (Δσ_{CTE}, Δσ_{LS}, and Δσ_{SS}) except Δσ_{GN}. Now Eq. (2) can be modified as σ_{ACGN}−Δσ_{CTE}=σₘ+σ_{LS}+Δσₛₛ+Δσ_{GN} where the thermally induced residual stress (Δσ_{CTE}) in Ni is in tension and, therefore, −Δσ_{CTE} becomes a positive value. Now the left and right sides (see L and R in FIG. 7) of the modified equation can be plotted together to estimate how Δσ_{GN} depends on two parameters, i.e., wire diameter and CVD temperature. The specific values for each strengthening effect are listed in FIG. 22.

FIG. 7 confirms that the yield behavior of ACGN depends on both wire diameter and CVD temperatures. To discuss details on possible mechanisms, it is important to remind that the use of different CVD temperatures concurrently alters two scale parameters, the average grain size (d) of Ni and the thickness (t_{mGr}) of mGr. For example, the ACGN wires processed at 800° C. (or simply ACGN_800) are coated by mono- or bi-graphene layer(s) while d becomes wire-diameter-dependent. These two microstructural features—the small graphene-to-volume ratio and the transition in Ni from poly- to single-crystalline-like grain structures—may offer feasible explanations for the yield behavior of ACGN_800. First, Δσ_{LS} and ΔΥ_{CTE} are insignificant regardless of wire diameters because nickel dominates the overall mechanical behavior due to the small volume fraction. Second, Δσ_{GN} does not appear to be diameter-dependent, while its contribution, 46-62 MPa, is still considerable. This result contradicts the previous size-dependent argument using Eq. 4. Note that Eq. 2 does not account for the observed microstructural transition in Ni and, thus, fails to capture both the graphene-nickel interfacial interplay and the microstructural transition. To support this point, N_{d}/L (see FIG. 8) was experimentally estimated for as-received Ni wires as well as annealed wires at 800 and 1000° C. using Eq. 3 and experimental data (measured average grain sizes and wire diameters in Table 1). As a reminder, the trend of N_{d}/L captures important microstructural features of a Ni wire, e.g., N_{d}/L>>1 and ≈0 indicate poly- and single-crystalline structures, respectively. It is important to note that the values of N_{d}/L for as-received wires are much larger than 1 regardless of wire diameter. In contrast, annealed wires show the transition from poly- to single-crystalline-like structures, i.e., formation of bamboo-like grain structure as N_{d}/L approaches 1. It is known that yield and post-yield behaviors of poly- and single-crystalline Ni are significantly different.

Furthermore, it appears that Eq. 2 is more suitable to analyze ACGN_1000 because of two reasons. First, ACGN_1000 is coated by about 40 graphene layers and the number of grains in Ni becomes less sensitive to wire diameter, e.g., even the largest ACGN_1000 has about 1.4 grains in its cross section (see the inset of FIG. 8) and, as a result, it can be argued that the effect of microstructural transition is less pronounced. Based on these, Eq. 2 was used to estimate Δσ_{GN} for ACGN_1000 without the unaccounted effect. The contribution of direct load sharing (Δσ_{LS}) increases for smaller wire diameter, i.e., 6.72, 26.86, and 53.71 MPa for 100, 25, and 12.5 μm, respectively. Despite Δσ_{LS}, the yield strength of ACGN_1000, when compared to annealed Ni wires, decreases more than what can be explained by thermal grain growth using the Hall-Petch effect. This discrepancy can be explained by Δσ_{CTE}, thermally induced tensile residual stress in Ni, i.e., 24, 94, and 184 MPa for 100, 25, and 12.5 μm, respectively. Finally, the diameter-dependent Δσ_{GN} is obtained by combining all experimental and theoretical analyses, i.e., 71.81, 96.66, and 162.82 MPa for 100, 25, and 12.5 μm, respectively.

In sum, the possible enhancement mechanisms of graphene-coated Ni (ACGN) wires have been discussed by comparing the yield strength between ACGN and annealed Ni (Ani) wires. In the theoretical prediction, three mechanisms are effective on ACGN wires: solid solution strengthening (Δσ_{SS}), residual stress (Δσ_{CTE}), and load-sharing mechanism (Δσ_{LS}). And it is hypothesized (without being bound by a specific theory) that the gap between the experimental and theoretical approaches indicates the key strengthening effect of graphene (Δσ_{GN})-interaction between the graphene and dislocation during plastic deformation. Although the size-dependent enhancement trend in ACGN is observed, i.e., the amount of enhancement increased with reducing the diameter of wire, the underlying strengthening mechanism(s) is still unclear due to the combination of several effects simultaneously. Exploring the exact effect of the observed microstructural transition from poly- to single-crystalline structures on mechanical responses of ACGC and mGr-Ni interplay can be an interesting topic, e.g., by tightly controlling grain size of Ni.

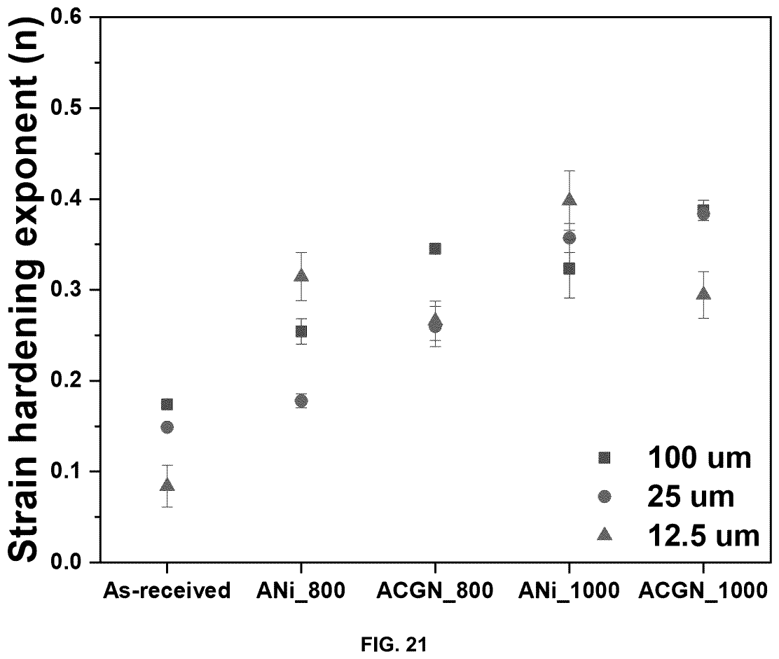

Post-yield behavior: The stress-strain behavior after yield and post-mortem SEM image analyses of the fracture surface (see FIG. 2A, FIG. 2B, FIG. 2C, FIG. 4A, FIG. 4B, and FIG. 4C, respectively) indicate that graphene and nickel interplay in a different way under two distinctive microstructures of Ni, namely, polycrystalline and bamboo-like structures. When comparing the annealed wires with different diameters, 12.5_ANi wires have a different stress-strain behavior compared to 100_and 25_ANi wires. It is known that dislocations formed in small-scale free-standing metals, such as micro/nanowires and thin films, under tension can readily escape to their free surfaces, e.g., due to attractive image forces (∝1/distance) from the surface. As a result, such small-scale metals exhibit less working hardening compared to their bulk counterpart and easily form a localized neck. This localized plastic deformation near the neck will likely reduce its cross section and, therefore, lead to material failure without contributing much to the value of the maximum strain due to extremely small length scale of the plastic zone compared to sample length. These characteristics can be seen in the annealed Ni wires (both ANi_800 and _1000) in the current work and is especially dominant in finer wires (12.5_ANi in current sturdy). It was also observed that the interesting different work hardening behavior in the ACGN and its counterparts. For example, the strain hardening trends of 100_ACGN_1000 is clearly different from that of 100_ANi_800 (see FIG. 2A, i.e., dσ/dε for ACGN increases faster than that ANi. Similar observations were made for 100_ACGN_800, 25_ACGN_800 and _1000 wires. Interestingly, 12.5_ACGN and _ANi wires show similar strain hardening behavior, e.g., they have similar dσ/ε as shown in FIG. 3C. For the quantitative measures of post-yield behavior, the Hollomon's equation below is used to obtain the strain hardening exponent (n):

$${σ}_{f} = K {ε}_{p}^{n} \qquad ( Eq . 7 )$$

where σ_{f} is an applied true flow stress, K a strength coefficient, εₚⁿ a true plastic strain, and n is a strain hardening exponent. Note that true stress and strain are used for the calculation of n from the engineering stress and strain (see the FIG. 21). n of ACGN is larger than that of ANi in 100 and 25 μm wires, for example, n=0.4317 for 100_ACGN_800 whereas n=0.3240 for 100_Ani_800. In contrast, the opposite trend was observed in 12.5 μm wires, e.g., n=0.28492 and 0.31393 for 12.5_ACGN_800 and _1000, respectively, which are lower than their counterparts (n=0.34266 and 0.4284 in 12.5_ANi_800 and _1000, respectively). This different work hardening behavior for 12.5-μm-diameter wires could be linked to N_{d}/L<1.

The post-mortem SEM analyses also suggest that N_{d}/L is an important factor that alters fracture behaviors. For 100- and 25-μm diameters, the failure of all wires, both as-received and annealed, was accompanied by conventional necking. However, 12.5-μm-diameter wires exhibit different failure mechanisms depending on their thermal history-conventional necking for as-received wires while formation of multiple slip bands within the wire's gauge length for thermally processed wires (i.e., annealed and ACGN wires). For the latter, material deformation of each wire, including axially elongated single crystal grains (see FIG. 17 at (b) and FIG. 17 at (c) for 12.5_ANi_800 and _1000, respectively), is likely accommodated by localized plastic deformation within each grain. The bamboo-like microstructures give a rise to this unique plastic deformation and may offer a reasonable explanation for the sudden stress drops/recoveries observed in stress-strain curves for 12.5-μm diameter (FIG. 2C). Stress drops may occur when a slip system is activated within a preferably oriented grain with respect to loading direction. During plastic deformation, the grain likely changes its orientation, which alters the resolved shear stress and deactivates the dislocation activities in the grain. When an applied load further increases, another single crystalline grain may have preferred orientation with respect to loading direction and another slip band can be formed in a different grain.

Another advantage of ACGN is that its ductility, defined by the normalized failure strain (¿), is similar or even better compared to ANi (\tilde{ε}=1.10˜1.58). Combined with more pronounced work hardening, ACGN achieves 39% to 124% improvement, indicated by \tilde{σ}=1.39˜2.24, in the ultimate tensile strength compared to ANi. Passivation of free surface by strong graphene may prevent dislocation escape to the free surface of Ni. Dislocation pileups near the graphene-nickel interface can increase flow stress and, therefore, likely hinder localized cross-sectional reduction (i.e., necking). The premise of this possible mechanism is the sufficiently strong interfacial strength at the graphene-nickel interface so that dislocation pileups can form at the interface. The maximum peak stress is around 12.4 GPa in the smallest interlayer distance of graphene (3.52 nm). When considering the transmission of dislocation in pure Ni, a previous report conducted MD simulations of the Ni bi-crystals with 132 unique configurations, consisting of 33 different structure and 4 different loading conditions and observed the transmission event below the 3 GPa. Previous reported studies suggest that the mGr-Ni interfacial strength is considerably higher than UTS of ACGN in the current work and, therefore, it is hypothesized (without being bound by a particular theory) that graphene can indeed passivate the free surfaces of fine Ni wires and prevent and/or minimize the dislocation escape to the surface. This conclusion is consistent with the two experimental observations of: more pronounced work hardening and improved ductility in ACGN compared to ANi, both caused by increased dislocation density in Ni due to additional dislocation pileups at the strong mGr-Ni interfaces.

In this study, axially bi-continuous graphene-coated nickel (ACGN) wires were synthesized and their mechanical properties characterized using the custom-built tensile tester. ACGN, owing to its unique microstructures, improves both strength and ductility, compared to its pure nickel counterpart and breaks the intrinsic strength-ductility trade-off in the conventional carbon-metal composites. For example, 25-μm-diameter ACGN composite wires concurrently achieve both 71.76% higher ultimate tensile strength and 58.24% increased failure strain, compared its pure metal matrix (Ni). This combined strength and ductility enhancement from axially continuous graphene structures is a significant technical advance directly compared to the current state-of-the-art graphene-metal composites. It is believed that the present disclosure has achieved the most advanced CMMCs with significant enhancement in both mechanical strength and ductility (\tilde{σ}>1 and \tilde{ε}>1).

Apart from the development and characterization of ACGN, possible mechanisms that govern its enhanced strength and ductility were investigated. After considering the solid solution strengthening (Δσₛₛ), load-sharing (Δσ_{LS}), and residual stress due to thermal mismatch (Δσ_{CTE}), experimental and theoretical analyses indicate that the unique graphene-metal interfaces along the composite wire is likely the main contributor for the observed mechanical enhancement. In other words, dislocations in Ni are accumulated against the strong graphene structure at the graphene-nickel interfaces. These additional dislocation pileups, by passivating the free surface of a fine Ni wire, prevent dislocation escape to the free surface, increase the flow stress near the graphene-nickel interface, and hinder premature formation of localized necking.

In sum, this work has demonstrated the superb mechanical properties of ACGN and identified the dominant mechanism for the combined strength-ductility enhancement. Material synthesis of innovative graphene-metal composites, combined with fundamental understanding on the underlying mechanisms of the enhanced material properties, may bring a technical paradigm shift in designing and tailoring microstructures of graphene-metal composites for various structural applications.

It is understood that the foregoing detailed description and accompanying examples are merely illustrative and are not to be taken as limitations upon the scope of the disclosure.

Various changes and modifications to the disclosed embodiments will be apparent to those skilled in the art. Such changes and modifications, including without limitation those relating to the chemical structures, substituents, derivatives, intermediates, syntheses, compositions, formulations, or methods of use of the technology, may be made without departing from the spirit and scope thereof.

For reasons of completeness, the following Embodiments are provided.

Clause 1. A composite wire material comprising: a core wire comprising nickel (Ni); and a layer on a circumferential surface of the core wire, the layer comprising graphene.

Clause 2. The composite wire material of clause 1, wherein the core wire has a diameter of about 10 μm to about 150 μm.

Clause 3. The composite wire material of clause 2, wherein the core wire has a diameter of about 12 μm to about 100 μm.

Clause 4. The composite wire material of any one of clauses 1-3, wherein the core wire comprises about 90% to about 100% pure nickel (Ni).

Clause 5. The composite wire material of any one of clauses 1-4, wherein the nickel (Ni) has a grain size of about 5 μm to about 25 μm.

Clause 6. The composite wire material of any one of clauses 1-5, wherein the layer comprises a plurality of graphene layers.

Clause 7. The composite wire material of clause 6, wherein the layer comprises about 1 to about 50 graphene layers.

Clause 8. The composite wire material of any one of clauses 1-7, wherein the layer has a thickness of about 0.3 nm to about 14 nm.

Clause 9. The composite wire material of any one of clauses 1-8, wherein an interface between the core wire and the layer comprises a matched lattice system between the nickel (Ni) and the graphene.

Clause 10. The composite wire material of any one of clauses 1-9, having a graphene-to-nickel (Ni) volume fraction of about 0.001 vol. % to about 0.5 vol. %.

Clause 11. The composite wire material of any one of clauses 1-10, having an ultimate strength of greater than or equal to 200 MPa.

Clause 12. The composite wire material of any one of clauses 1-11, having a yield strength of greater than or equal to 95 MPa.

Clause 13. The composite wire material of any one of clauses 1-12, having a failure strain of greater than or equal to 6%.

Clause 14. A method of making a composite wire material, the method comprising: annealing a core wire comprising nickel (Ni) at a temperature of about 800° C. to about 1000° C. under flowing mixed gaseous conditions comprising argon (Ar) and hydrogen (H₂); and coating graphene on a circumferential surface of the core wire to generate a layer comprising the graphene.

Clause 15. The method of clause 14, wherein the flowing mixed gaseous conditions comprise about 1400 standard cubic centimeters per minute (sccm) to about 1600 sccm argon (Ar) and about 75 sccm to about 125 sccm hydrogen (H₂) for about 5 minutes to about 15 minutes.

Clause 16. The method of clause 14 or 15, wherein coating graphene comprises vapor depositing benzene at a flow rate of about 5 sccm to about 25 sccm at about 800° C. to about 1000° C. for about 5 minutes to about 15 minutes.

Clause 17. The method of any one of clauses 14-16, wherein the core wire is cleaned under flowing mixed gaseous conditions comprising argon (Ar) and hydrogen (H₂) for about 5 minutes to about 1 hour prior to annealing.

Clause 18. The method of clause 17, wherein the flowing mixed gaseous conditions during the cleaning comprise about 650 sccm to about 850 sccm argon (Ar) and about 20 sccm to about 40 sccm hydrogen (H₂).

Clause 19. The method of clause 17 or 18, wherein the cleaning of the core wire, the annealing of the core wire, the coating of the core wire, or a combination thereof are done under vacuum.

Clause 20. The method of any one of clauses 14-19, wherein coating graphene generates one or more layers on the circumferential surface of the core wire, each layer comprising graphene.

What is claimed is:

1. A composite wire material comprising:
a core wire comprising nickel (Ni); and
a layer on a circumferential surface of the core wire, the layer comprising graphene.

2. The composite wire material of claim 1, wherein the core wire has a diameter of about 10 μm to about 150 μm.

3. The composite wire material of claim 2, wherein the core wire has a diameter of about 12 μm to about 100 μm.

4. The composite wire material of claim 1, wherein the core wire comprises about 90% to about 100% pure nickel (Ni).

5. The composite wire material of claim 1, wherein the nickel (Ni) has a grain size of about 5 μm to about 25 μm.

6. The composite wire material of claim 1, wherein the layer comprises a plurality of graphene layers.

7. The composite wire material of claim 6, wherein the layer comprises about 1 to about 50 graphene layers.

8. The composite wire material of claim 1, wherein the layer has a thickness of about 0.3 nm to about 14 nm.

9. The composite wire material of claim 1, wherein an interface between the core wire and the layer comprises a matched lattice system between the nickel (Ni) and the graphene.

10. The composite wire material of claim 1, having a graphene-to-nickel (Ni) volume fraction of about 0.001 vol. % to about 0.5 vol. %.

11. The composite wire material of claim 1, having an ultimate strength of greater than or equal to 200 MPa.

12. The composite wire material of claim 1, having a yield strength of greater than or equal to 95 MPa.

13. The composite wire material of claim 1, having a failure strain of greater than or equal to 6%.

14. A method of making a composite wire material, the method comprising:
annealing a core wire comprising nickel (Ni) at a temperature of about 800° C. to about 1000° C. under flowing mixed gaseous conditions comprising argon (Ar) and hydrogen (H₂); and
coating graphene on a circumferential surface of the core wire to generate a layer comprising the graphene.

15. The method of claim 14, wherein the flowing mixed gaseous conditions comprise about 1400 standard cubic centimeters per minute (sccm) to about 1600 sccm argon (Ar) and about 75 sccm to about 125 sccm hydrogen (H₂) for about 5 minutes to about 15 minutes.

16. The method of claim 14, wherein coating graphene comprises vapor depositing benzene at a flow rate of about 5 sccm to about 25 sccm at about 800° C. to about 1000° C. for about 5 minutes to about 15 minutes.

17. The method of claim 14, wherein the core wire is cleaned under flowing mixed gaseous conditions comprising argon (Ar) and hydrogen (H₂) for about 5 minutes to about 1 hour prior to annealing.

18. The method of claim 17, wherein the flowing mixed gaseous conditions during the cleaning comprise about 650 sccm to about 850 sccm argon (Ar) and about 20 sccm to about 40 sccm hydrogen (H₂).

19. The method of claim 18, wherein the cleaning of the core wire, the annealing of the core wire, the coating of the core wire, or a combination thereof are done under vacuum.

20. The method of claim 14, wherein coating graphene generates one or more layers on the circumferential surface of the core wire, each layer comprising graphene.
